(19) United States
(12) Patent Application Publication
(10) Pub. No.: US 2019/0072987 A1
(43) Pub. Date: Mar. 7, 2019

(54) VALVE CONFIGURATIONS FACILITATING CLEARING, CLEANING, DRYING, AND BURST FORMATION FOR MICROFLUIDIC DEVICES, FLUIDIC ARRANGEMENTS, AND OTHER SYSTEMS

(71) Applicant: NRI R&D PATENT LICENSING, LLC, San Antonio, TX (US)

(72) Inventors: Lester F. LUDWIG, San Antonio, TX (US); Catherine LUK, San Francisco, CA (US); Sulu LALCHANDANI, San Francisco, CA (US); Ying CHEN, San Francisco, CA (US)

(21) Appl. No.: 16/179,825

(22) Filed: Nov. 2, 2018

Related U.S. Application Data
(60) Provisional application No. 62/580,841, filed on Nov. 2, 2017.

(51) Int. Cl. G05D 7/06; F16K 99/00

(52) U.S. Cl. CPC G05D 7/0694; B81B 2207/01; B81B 2201/054; F16K 99/0001

(57) ABSTRACT

A software-controlled triangle-topology valve-cluster for use at taps or conduit junction points that facilitate fluid-based clearing, gas-based clearing, solvent-based cleaning, gas drying, small-volume burst formation, abandoned-material return, and other valuable operations is disclosed. The invention provides better contamination performance than simple passive or valve-chaperoned “T”-topology junctions. The valve-cluster arrangement can be implemented or approximated in various ways. For faster performance, simplified programming, or other reasons “macro” controllability can be provided for operating groups of valves in one or more of simultaneous operation, time-defined sequenced operation, or conditional operation, and such macros can further provide for conditional inputs or parameters. Such “macro,” “conditional-macro,” and “parameterized-macro” control could be implemented in software, firmware, and/or hard-wired logic. The invention can be used in reusable or reconfigurable microfluidic systems, facilitate decontaminated and green disposal and recycling of microfluidics, and other fluidic applications. Features of the invention can also be extended to gas transport.

### CROSS-REFERENCE TO RELATED CASES

This application claims the benefit of U.S. Provisional Application No. 62/580,841, filed Nov. 2, 2017, the disclosures of which are incorporated herein in their entireties by reference.

### COPYRIGHT & TRADEMARK NOTICES

A portion of the disclosure of this patent document may contain material, which is subject to copyright protection. Certain marks referenced herein may be common law or registered trademarks of the applicant, the assignee or third parties affiliated or unaffiliated with the applicant or the assignee. Use of these marks is for providing an enabling disclosure by way of example and shall not be construed to exclusively limit the scope of the disclosed subject matter to material associated with such marks.

### BACKGROUND OF THE INVENTION

### 1. Field of the Invention

The present application pertains to software-controlled fluidic transport hardware and operation processes for microfluidic systems and more specifically to valve arrangements for use at taps to fluidic conduits and fluidic conduit junction points that facilitate fluid-based clearing, gas-based clearing, solvent-based cleaning, and/or drying operations.

### 2. Related Art

There is a great deal of literature on “Micro Total Analysis Systems” (μTAS). The New Renaissance Institute's “Fluidic Microprocessors” and component technologies such as its “Microfluidic Bus” are described in the at least the following U.S. patents and U.S. patent applications, among others:
New Renaissance Institute software-reconfigurable microfluidic system technologies:
   U.S. Pat. No. 9,636,655 “Software-Reconfigurable Conduit and Reaction Chamber Microfluidic Arrangements for Lab-On-A-Chip and Miniature Chemical Processing Technologies”
   U.S. patent application Ser. No. 15/499,767 “General-Purpose Reconfigurable Conduit and Reaction Chamber Microfluidic Arrangements for Lab-On-Chip and Miniature Chemical Processing” (PGP 2017/0225163)
   U.S. patent application Ser. No. 13/815,757 “Removable Fluidics Structures for Microarray, Microplates, Sensor Arrays, and Other Removable Media” (PGP 2014/0274814)
   U.S. patent application Ser. No. 13/761,142 “Microprocessor-Controlled Microfluidic Platform for Pathogen, Toxin, Biomarker, and Chemical Detection with Removable Updatable Sensor Array for Food and Water Safety, Medical, and Laboratory Applications” (PGP 2013/0217598);
New Renaissance Institute software-controlled microfluidic transport bus technologies:
   U.S. Pat. No. 8,032,258 “Multi-Channel Chemical Transport Bus for Microfluidic and Other Applications”
   U.S. Pat. No. 8,606,414 “Multi-Channel Chemical Transport Bus Providing Short-Duration Burst Transport Using Sensors for Microfluidic and Other Applications”
   U.S. Pat. No. 8,812,163 “Multi-Channel Chemical Transport Bus with Bus-Associated Sensors for Microfluidic and Other Applications”
   U.S. patent application Ser. No. 14/335,763 “Multi-Channel Chemical Transport Bus with Bus-Associated Sensors for Microfluidic and Other Applications;”
New Renaissance Institute software-controlled microfluidic chemical synthesis and analysis:
   U.S. Pat. No. 8,734,732 “Chemical Synthesis and Analysis via Integrated, Sequential and Series-Parallel Photochemical and Electrochemical Processes for Microfluidic, Lab-On-A-Chip, and Green-Chemistry Applications”
   U.S. Pat. No. 8,877,143 “Chemical Synthesis and Analysis via Integrated, Sequential and Series-Parallel Photochemical and Electrochemical Processes for Microfluidic, Lab-On-A-Chip, and Green-Chemistry Applications”
   U.S. patent application Ser. No. 14/530,779 “Chemical Synthesis and Analysis via Integrated, Sequential and Series-Parallel Photochemical and Electrochemical Processes for Microfluidic, Lab-On-A-Chip, and Green-Chemistry Applications;”
New Renaissance Institute software-controlled emulation of microfluidic system technologies:
   U.S. Pat. No. 8,560,130 “Software-Controlled Lab-on-a-Chip Emulation”
   U.S. Pat. No. 9,802,190 “Modular computer-controlled multistep chemical processing system for use in laboratory automation or chemical production spanning a plurality of scales”
   U.S. Pat. No. 8,594,848 “Reconfigurable Chemical Process Systems”
   U.S. patent application Ser. No. 15/717,024 “Modular Computer-Controlled Multistep Chemical Processing System for Use in Laboratory Automation or Chemical Production” (PGP 2018/0015463);
New Renaissance Institute software and system development environment:
   U.S. Pat. No. 8,396,701 “Software Systems for Development, Control, Programming, Simulation, and Emulation of Fixed and Reconfigurable Lab-on-a-Chip Devices.”

New Renaissance Institute software-controlled of fluidic transport and operation processes for fluidic and microfluidic systems have been presented, for example, in the following patents and patent applications involving one of the present inventors:
U.S. Pat. No. 9,636,655 and U.S. patent application Ser. No. 15/499,767 describe various approaches to and aspects of software controlled multichannel microfluidic systems with cleaning, clearing, drying, and reconfiguration capabilities.
U.S. Pat. Nos. 8,032,258, 8,606,414, and 8,812,163 which describe various approaches to and aspects of software controlled multichannel microfluidic chemical transport busses and related fluidic systems and methods;
U.S. Pat. No. 8,396,701 and pending U.S. patent application Ser. No. 13/757,662 which describe software systems and methods for development, control, programming, simulation, and emulation of fixed and reconfigurable lab-on-a-chip devices;
U.S. Pat. No. 9,636,655 and pending U.S. patent application Ser. No. 15/499,767 which describes software reconfigurable conduit and reaction chamber microfluidic arrangements for lab-on-a-chip and miniature chemical processing technologies;
Pending U.S. patent application Ser. No. 13/761,142 and PCT/US 2013/025002 which describe microprocessor-controlled microfluidic platform for pathogen, toxin, biomarker, and chemical detection with removable updatable sensor array for food and water safety, medical, and laboratory applications;
Pending U.S. patent application Ser. No. 13/815,757 which describes removable fluidics structures for microarray, microplates, sensor arrays, and other removable media;
U.S. Pat. No. 9,994,889 which describes fluidic and microfluidic based cell incubator and cellular culture technologies;
U.S. Pat. No. 9,646,133 and pending U.S. patent application Ser. No. 14/216,420 which describe computer-controlled microfluidic systems and instrumentation for next-step biological signaling network research, disease research, drug discovery, cell biology, and other applications;
U.S. Pat. Nos. 8,560,130 and 9,802,190 which describe systems and methods for emulation of fixed and reconfigurable lab-on-a-chip devices and modular computer-controlled multistep chemical processing systems for use in laboratory automation or chemical production;
U.S. Pat. No. 8,594,848 which describes laboratory-glassware-based reconfigurable chemical process systems, using for example controllable stopcock adapters such as that taught in U.S. Pat. No. 8,734,736 and pending U.S. patent application Ser. No. 12/899,551.

As mentioned above, U.S. Pat. No. 8,396,701 describes software systems and methods for development, control, programming, simulation, and emulation of fixed and reconfigurable lab-on-a-chip devices such as those described in U.S. Pat. Nos. 8,606,414, 8,560,130, 9,646,133, 9,636,655, 9,994,889, and pending U.S. patent application Ser. Nos. 13/761,142, 14/216,420, 13/815,757, and related cases.

### 3. Overview of the Invention

In microfluidic systems involving a side tap on a through-path conduit or involving a three-conduit junction that additionally provides one or more of fluid-based clearing, gas-based clearing, solvent-based cleaning, and/or drying operations, a passive “T”-topology junction can suffer from poor clearing and cleaning results. The performance can be improved by adding valves, although simple, ordinary on/off valves are far from being able to solve the problems as will be shown.

The present invention provides a triangle-topology valve cluster that can be used to replace “T”-topology junctions commonly employed to provide a side tap in a through-path conduit or a three-conduit junction.

Although most microfluidic systems described in the literature to date are either entirely passive or have limited process control capability, future microfluidic systems (such as New Renaissance Institute's “Fluidic Microprocessors” and component technologies such as its “Microfluidic Bus”) and longer-term programs such as “Micro Total Analysis Systems” (μTAS) entail the sequenced control of a great number of valves and other controllable entities (motorized or sequenced-pulse pumps, photochemical and optical sensor illumination, thermal processing, sensor measurement capture, active mixer elements, electrochemical electrodes and hardware, sonochemical and surface-acoustic wave elements, etc.) to implement a one-pass or continuous process.

Further, in the case of multiple-use systems supporting repeated operation of one-pass processes on different analysis samples or for repeated batch extraction or synthesis, there can beneficially be fluid-based clearing, gas-based clearing, solvent-based cleaning, solvent-drying operations, and other drying operations, and in some cases, current process shutdown and new process startup steps.

Additionally, for microfluidic system maintenance, servicing, replacement, or hibernation purposes there can also be similar processes of sequenced control of many valves and other controllable entities for the purposes of process shutdown, device shutdown, device startup, and process startup steps.

Yet further, in the case of reconfigurable microfluidic systems, there can beneficially be current process shutdown, fluid-based clearing, gas-based clearing, solvent-based cleaning, drying operations, reconfiguration, and new process startup steps.

A key aspect of the advanced future microfluidic systems described above is these systems will invariably comprise side tap on a through-path conduit or involving three-conduit junction. In microfluidic systems involving a side tap on a through-path conduit or involving three-conduit junction that additionally provides one or more of fluid-based clearing, gas-based clearing, solvent-based cleaning, and/or drying operations, a “T”-topology junction can suffer from poor clearing and cleaning results. A few examples of some of the contamination scenarios and difficulties in clearing, cleaning, and drying are provided in FIGS. 16b-f, FIGS. 18b-g, and associated discussions in U.S. Pat. No. 9,363,655.

Importantly, many advanced and future microfluidic systems feature such passive “T”-topology junctions. Also, microfluidic software-controlled multichannel microfluidic chemical transport busses such as those described in U.S. Pat. Nos. 8,032,258, 8,606,414, and 8,812,163 can include such passive “T”-topology junctions. Reconfigurability and reusability features, in addition to new possible green disposal and recycling approaches, can require clearing, cleaning, and drying capabilities.

The present invention addresses these needs and problems.

### SUMMARY OF THE INVENTION

For purposes of summarizing, certain aspects, advantages, and novel features are described herein. Not all such advantages can be achieved in accordance with any one particular embodiment. Thus, the disclosed subject matter can be embodied or carried out in a manner that achieves or optimizes one advantage or group of advantages without achieving all advantages as taught or suggested herein.

The present invention teaches a triangle-topology valve cluster that can be used to replace “T”-topology junction commonly employed to provide a side tap in a through-path conduit or three-conduit junction.

In one aspect of the invention, the invention provides software-controlled fluidic transport hardware and operation processes for microfluidic systems, and more specifically to valve arrangements for use at taps to fluidic conduits and fluidic conduit junction points that facilitate fluid-based clearing, gas-based clearing, solvent-based cleaning, and/or drying operations.

In another aspect of the invention, a triangle-topology valve-cluster providing better contamination performance, and which better facilitates various types of clearing, cleaning, and drying capabilities that simple passive “T”-topology junctions or valve-chaperoned “T”-topology junctions, is provided.

In another aspect of the invention, valve-cluster arrangements can serve as transfer points for applying gas pressure for propelling a fluid through valves and conduits. This is important because gas compresses under pressure, and as a result, long transmission paths require increasing amounts of gas pumping and can slow down the rate of transfer.

In another aspect of the invention, valve-cluster arrangements can be used to introduce clearing gases into the conduits and other structures of microfluidic devices and other fluidic systems.

In another aspect of the invention, valve-cluster arrangements can be used to introduce cleaning solvents into the conduits and other structures of microfluidic devices and other fluidic systems.

In another aspect of the invention, valve-cluster arrangements can be used to introduce drying gases into the conduits and other structures of microfluidic devices and other fluidic systems.

In another aspect of the invention, valve-cluster arrangements can be used facilitate reusable microfluidic devices.

In another aspect of the invention, valve-cluster arrangements can be used facilitate reconfigurable microfluidic devices.

In another aspect of the invention, valve-cluster arrangements can be used facilitate decontamination of recyclable or safe-disposal microfluidic devices.

In another aspect of the invention, valve-cluster arrangements can be used to return unused materials abandoned in conduits and valve passages along a transmission path back to their source.

In another aspect of the invention, valve-cluster arrangements can be used to return unused materials abandoned in conduits and valve passages along a transmission path back to another location.

In another aspect of the invention, valve-cluster arrangements can be used to create small-volume bursts of fluid.

In another aspect of the invention, valve-cluster arrangements can be controlled by “macro” control operations so as to operate groups of valves at the same time.

In another aspect of the invention, valve-cluster arrangements can be controlled by “macro” control operations so as to operate groups of valves in a time-defined sequence.

In another aspect of the invention, implementations involving “macro” control for operating groups of valves can include provisions for at least one conditional input that can affect the behavior of the group operation by a macro.

In another aspect of the invention, implementations involving “macro” control for operating groups of valves can include provisions for at least one parameter that can affect the behavior of the group operation by a macro.

In another aspect of the invention, “macro” control be implemented in one or more of software, firmware, and/or hard-wired logic.

In another aspect of the invention, valve-cluster arrangements can be implemented or approximated in various manners and with variations.

### BRIEF DESCRIPTION OF THE DRAWINGS

The above and other aspects, advantages, and features will be more apparent from the following description of certain embodiments taken in conjunction with the accompanying drawings, in which:

FIG. 1, adapted from FIG. 7b of U.S. Pat. No. 8,396,701, depicts an example global view of an example software and systems development environment.

FIG. 2 depicts an example of elements and interconnections among elements in a complex that can be arranged to be configured under software control.

FIG. 3a, adapted from FIG. 14 of U.S. Pat. Nos. 8,032,258 and 8,606,414, depicts simple example contiguous flow transport through a simple example transport bus for microfluidic and other applications; the depicted fluidic flow (signified with superimposed heavy line) is enabled by the two open valves at the top of the figure, one of these valves connecting the second-to-left vertical conduit with the top horizontal tapped bus conduit, and the other of these valves connecting the second-to-right vertical conduit with the same top horizontal tapped bus conduit. The many passive “T”-topology junctions throughout the simple example microfluidic bus system are noted.

FIG. 3b, adapted from FIG. 9d of U.S. Pat. Nos. 8,032,258 and 8,606,414, depicts example contamination processes (signified with superimposed dashed heavy lines) resultant from the fluid flow (signified with superimposed heavy line) depicted in FIG. 3a.

FIG. 3c, adapted from FIG. 9a of U.S. Pat. Nos. 8,032,258 and 8,606,414, depicts an example enhanced variation of the chemical transport bus of FIG. 3a wherein additional local valves are added so as to closely surround each “T”-topology junction with three valves, one for each conduit meeting at the 3-way junction point.

FIG. 3d, adapted from FIG. 18b of U.S. Pat. Nos. 8,032,258 and 8,606,414, depicts the example enhanced chemical transport bus depicted in FIG. 3c in the process of transporting two bursts of fluidic material which can transported through the chemical transport bus conduits, for example, by applied controlled propelling gas pressure and/or electrokinetic forces.

FIG. 4 depicts an example transaction-myopic system-level operation of a software controlled chemical transport bus system comprising sequences among five classes of example states, idle, fluid flow, gas-pressure clearing, solvent-based cleaning, and gas-based drying.

FIG. 5 depict a simplified example system comprising two chambers, each comprising a dedicated valve-gated pressure passage and a fluid transport port.

FIG. 6 depicts a valve-chaperoned “T”-topology comprising three SPST (on/off) gate valves connected on one side to an associated external port (Port A, Port, B, and Port C respectively) and on the other side to a flow T-juncture.

FIG. 7 comprises a “triangle”-topology valve-cluster having Port A connected to the COM port of its associated SPDT valve and having Port B connected to the COM port of its associated SPDT valve.

FIG. 8 depicts a variation on example “triangle”-topology valve-cluster arrangement shown in FIG. 56 comprising having the COM port of the SPDT valve associated with Port A connected to the COM port of the SPDT valve associated with Port B.

FIG. 9 illustrates an example transport flow (top drawing), an example clearing/cleaning flow between valve C and valve B (middle drawing), and an example clearing/cleaning flow among valve C and valve A (bottom drawing) for the example arrangement of FIG. 6.

FIG. 10 illustrates an example transport flow (top drawing), an example clearing/cleaning flow among valve C and valve B (middle drawing), and an example clearing/cleaning flow among valve C and valve A (bottom drawing) for the example arrangement of FIG. 7.

FIG. 11 illustrates an example transport flow (top drawing), an example clearing/cleaning flow among valve C and valve B (middle drawing), and an example clearing/cleaning flow among valve C and valve A (bottom drawing) for the example arrangement of FIG. 8.

FIG. 12 depicts a simplified example system comprising two chambers, each comprising a dedicated valve-gated pressure passage and a fluid transport port, and further incorporating multiple instances of the valve cluster depicted in FIG. 6 into the configuration depicted in FIG. 5; FIG. 12 further depicts an example initial situation where a fluid present in Chamber 1. In this example, Chamber 1 can be regarded as the fluid source.

FIG. 13 depicts an example situation where gas pressure provided by pressure passage 1 going through the gas-pressure gating valve 1 powered now into an open position, resulting in pushing a fluid front into the outgoing conduit. Valves 2Y, 2Z, 3Y, 3Z, 4Y, 4Z, 5Z, and pressure passage 6 valves are open to vent the displaced gas ahead of the fluid front out of Chamber 2 through pressure passage 6.

FIG. 14 depicts an example situation where gas pressure provided by pressure passage 1 further pushing a fluid front into valve cluster 2 (comprising valves 2X, 2Y, 2Z), wherein flow valves 2Y and 2Z are open and gas-pressure gating valve 2X remains closed as it was in FIGS. 12 and 13. Valves 3Y, 3Z, 4Y, 4Z, 5Z, and pressure passage 6 valves are open to vent the displaced gas ahead of the fluid front out of Chamber 2 through pressure passage 6.

FIG. 15 depicts an example situation where the pressure passage valve 1 closed and pressure passage valve 2X open, letting the pressure passage 2 open, further pushing a fluid front past valve cluster 2 approaching valve 3Y. Valves 3Y, 3Z, 4Y, 4Z, 5Z, and pressure passage 6 valves are open to vent the displaced gas ahead of the fluid front out of Chamber 2 through pressure passage 6.

FIG. 16 depicts an example subsequent situation where gas pressure passage valve 2X and flow valve 3Y are closed and valve 3X is open allowing gas pressure from pressure passage 3 to travel past valve 3Z. Valves 4Y, 4Z, 5Z, and pressure passage 6 valves are open to vent the displaced gas ahead of the fluid front out of Chamber 2 through pressure passage 6.

FIG. 17 depicts an example situation where gas pressure passage valve 3X is closed and gas pressure passage valve 4X is open allowing the pressure from gas pressure passage 4 to transport fluid through valve 4Z, pushing the fluid towards valve 5Y. Valves 5Z and pressure passage 6 valves are open to vent the displaced gas ahead of the fluid front out of Chamber 2 through pressure passage 6.

FIG. 18 depicts an example situation where gas pressure passage valve 4X closed and gas pressure passage valve 5X is open allowing the pressure from pressure passage 5 to push the fluid front past valve 5Z into chamber 2 (the destination).

FIGS. 19-23 depict similar example operation steps for the same arrangement that result in a flow travelling in the opposite direction, employing Chamber 2 as the source and Chamber 1 as the destination.

FIG. 24 depicts a simplified example system comprising two chambers, each comprising a dedicated valve-gated pressure passage and a fluid transport port, and further incorporating multiple instances of the valve cluster depicted in FIG. 8 into the configuration depicted in FIG. 5.

FIG. 25 depicts an example initial situation where a fluid present in Chamber 1. In this example Chamber 1 can be regarded as the fluid source.

FIG. 26 depicts gas pressure provided by pressure passage 1 going through the gas-pressure gating valve 1 powered now into an open position.

FIG. 27 depicts the pressure passage valve 1 closed and pressure passage valve 2 open, letting the pressure passage 2 open.

FIG. 28 depicts the fluid going further and exceeding valve 2B with the pressure coming from pressure passage 2 and approaching valve 3A.

FIG. 29 depicts the valve 2 turned off and valve 3 turned on allowing the pressure from pressure passage 3 to circulate through 3C, 3A, and finally 3B pushing the fluid further passed valve 3B.

FIG. 30 depicts the valve 3 turned off and valves 4 turned on allowing the pressure from pressure passage 4 to circulate through 4C, 4A, and 4B pushing the fluid even further passed valve 4B.

FIG. 31 depicts the valve 4 turned off and valve 5 turned on allowing the pressure from pressure passage 5 to circulate through 5 C, 5A, then 5B pushing the fluid into Chamber 2, the destination.

FIGS. 32-36 depict example operation steps for the same arrangement that result in a flow travelling in the opposite direction, employing Chamber 2 as the source and Chamber 1 as the destination.

FIG. 37a depicts an example approximation of a SPDT valve with two very-closely adjacent SPDT valves.

FIG. 37b depicts an example brute-force implementation of the triangle-topology valve cluster of FIG. 8 using three instances of the SPDT valve approximation of FIG. 37a.

FIG. 37c depicts an example simplified implementation of the approximated triangle-topology valve cluster of FIG. 37b wherein redundant valves have been removed.

FIGS. 38a and 38b depict two four-port examples providing potentially useful functions for localized cleaning/clearing/drying flow insertions or implementing more complicated fluidic architecture junctions.

### DETAILED DESCRIPTION

In the following description, reference is made to the accompanying drawing figures which form a part hereof, and which show by way of illustration specific embodiments of the invention. It is to be understood by those of ordinary skill in this technological field that other embodiments may be utilized, and structural, electrical, as well as procedural changes may be made without departing from the scope of the present invention.

In the following description, numerous specific details are set forth to provide a thorough description of various embodiments. Certain embodiments may be practiced without these specific details or with some variations in detail. In some instances, certain features are described in less detail so as not to obscure other aspects. The level of detail associated with each of the elements or features should not be construed to qualify the novelty or importance of one feature over the others.

### 1. BACKGROUND

The present application pertains to the software-control of fluidic transport and operation processes for microfluidic systems, and in particular to valve arrangements for use at taps to fluidic conduits and fluidic conduit junction points that facilitate fluid-based clearing, gas-based clearing, solvent-based cleaning, and/or drying operations.

Although most microfluidic systems in the literature to date are either entirely passive or have limited process control capability, future microfluidic systems (such as New Renaissance Institute's “Fluidic Microprocessors” and component technologies such as its “Microfluidic Bus”) and longer-term programs such as “Micro Total Analysis Systems” (μTAS) entail the sequenced control of a great number of valves and other controllable entities (motorized or sequenced-pulse pumps, photochemical and optical sensor illumination, thermal processing, sensor measurement capture, active mixer elements, electrochemical electrodes and hardware, sonochemical and surface-acoustic wave elements, etc.) to implement a one-pass or continuous process.

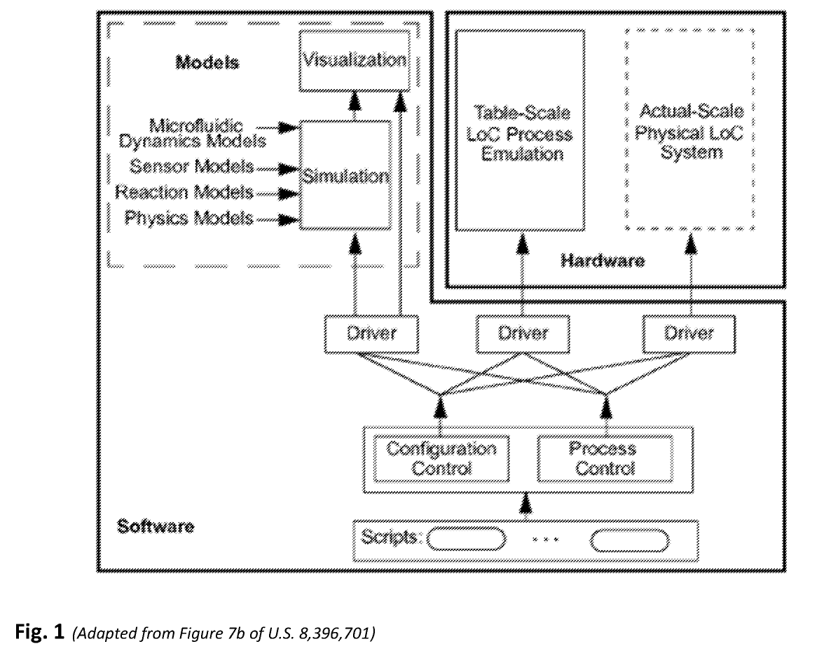

FIG. 1, adapted from FIG. 7b of U.S. Pat. No. 8,396,701, depicts an example global view of an example software and systems development environment. Such a software environment embodiment could, for example, be configured or directed to the development, study, or operation of fluidic devices which do or do not have controllable configuration or reconfiguration abilities. Such a software environment embodiment can, for example, be used for progressive and/or interspersed simulation, emulation, and, where applicable, direct control of fluidic devices from one or more scripts and/or files. Such a software environment embodiment can, for example, employ common configuration scripts, files, or other techniques to configure the numerical simulation system, the physical emulation system, as well as actual fluidic devices. The same configuration scripts, files, or techniques can, for example, be used to configure numerical modeling system and emulation systems. This allows for the actual or prototype controllable microfluidic device to be operated by the system and compared with simulation and/or emulation results. Additionally, arrangements can include integration of configuration control together with process control, permitting scripts, files, or other techniques to freely combine configuration commands and process commands. Other approaches are possible as is clear to one skilled in the art.

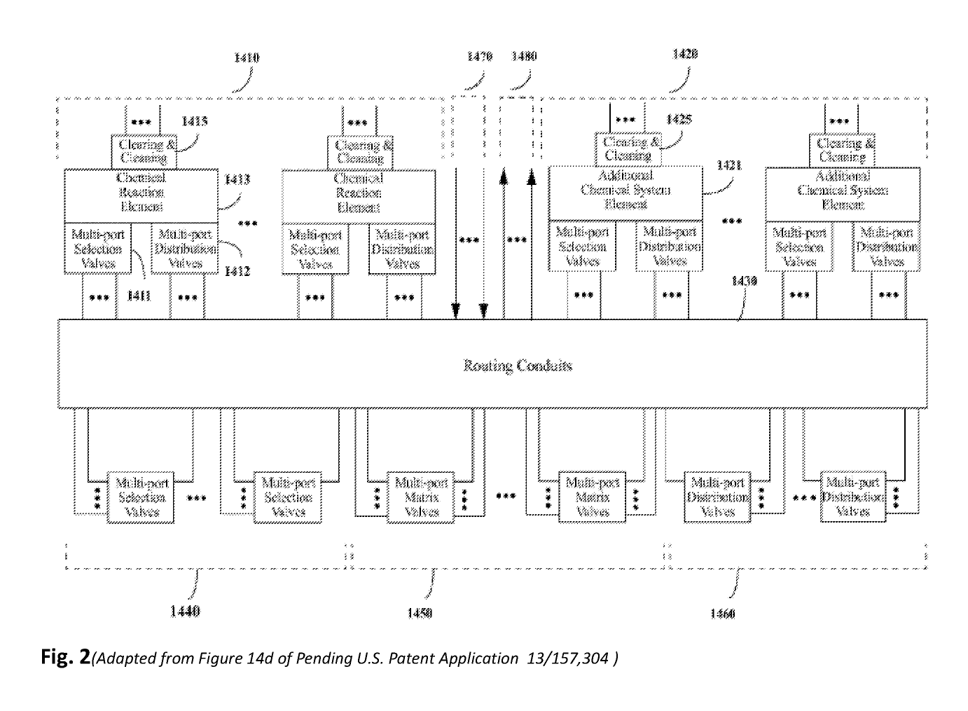

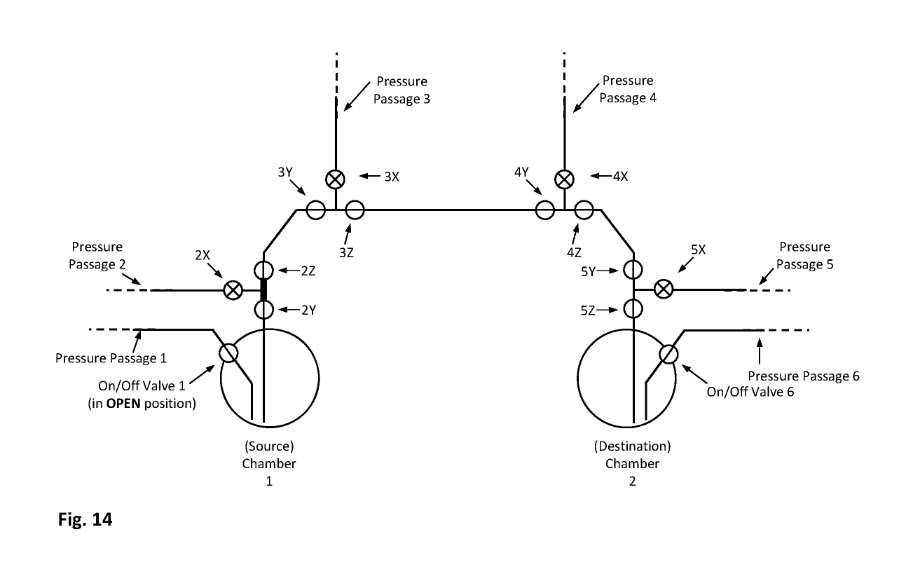

FIG. 2 adapted from FIG. 14d of U.S. Pat. No. 9,646,133, depicts an example software-controlled/software-reconfigurable conduit and reaction chamber microfluidic arrangements for lab-on-a-chip and miniature chemical processing technologies. Example software controllable elements include fluid/gas/slurry routing and gating valves, chemical/biochemical reaction chambers, pumps or other (e.g. electrokinetic) flow-drivers, mixers, thermoelectric devices, light-emitting devices (for photochemical excitation, photosensitization stimulation (for example for localized nitric-oxide donor molecules), florescent marker stimulation, absorption/transmission spectroscopy, colorimetric analysis, etc.), electrochemical synthesis electrodes, electrochemical (amperometry/voltammetry/coulometry) analysis electrodes, instrumentation and imaging systems, etc.

Further regarding transport, as mentioned above, U.S. Pat. No. 8,032,258 and related cases describe various approaches to and aspects of software controlled multichannel microfluidic chemical transport busses and related fluidic systems and methods.

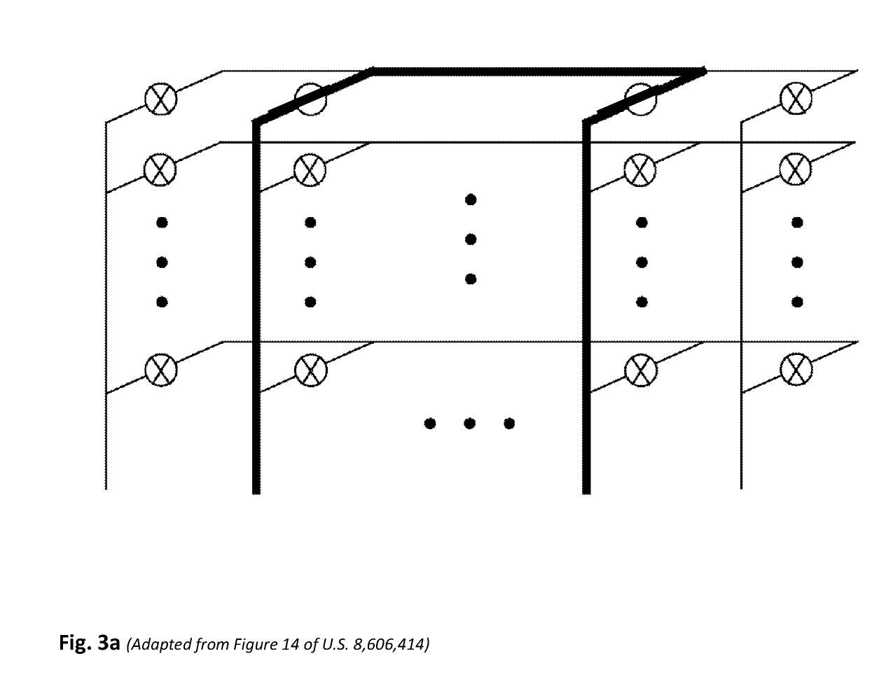

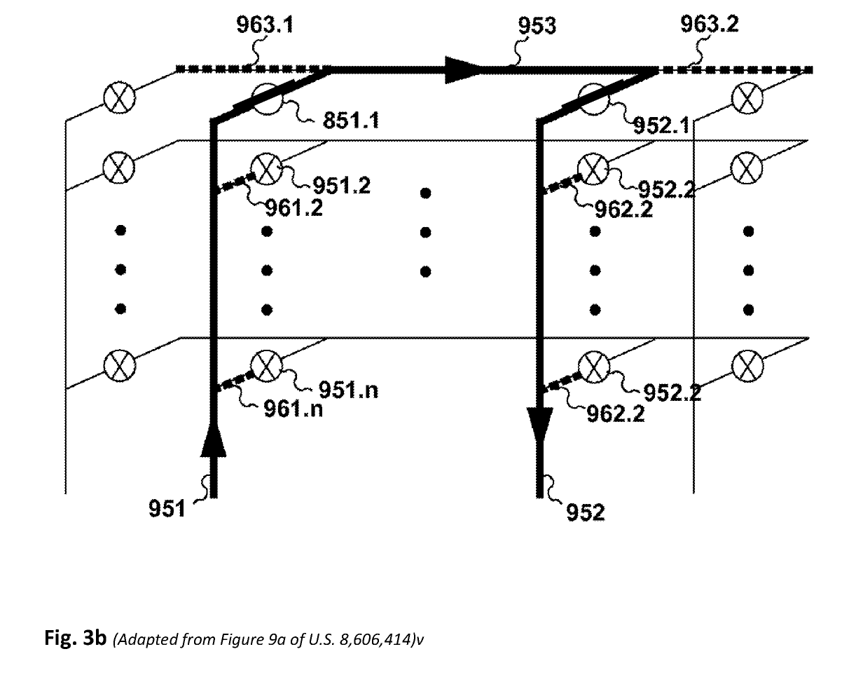

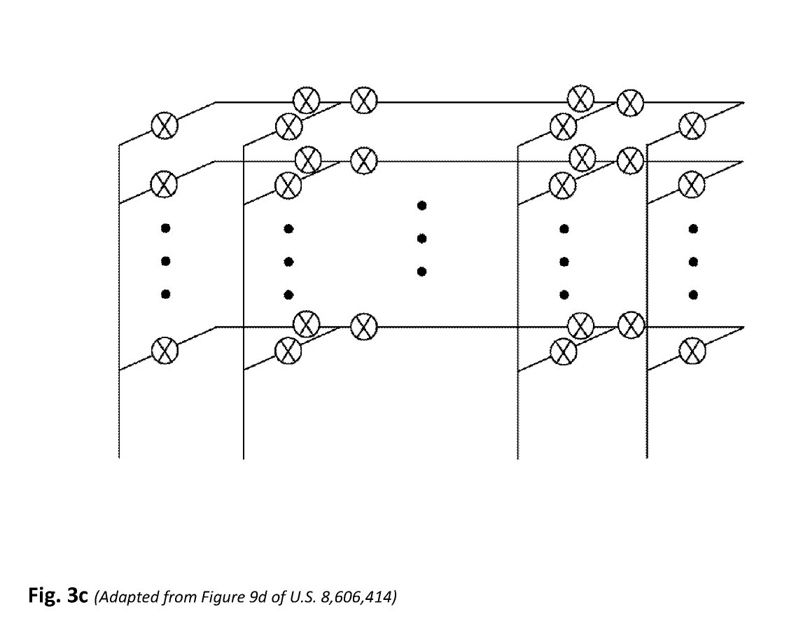

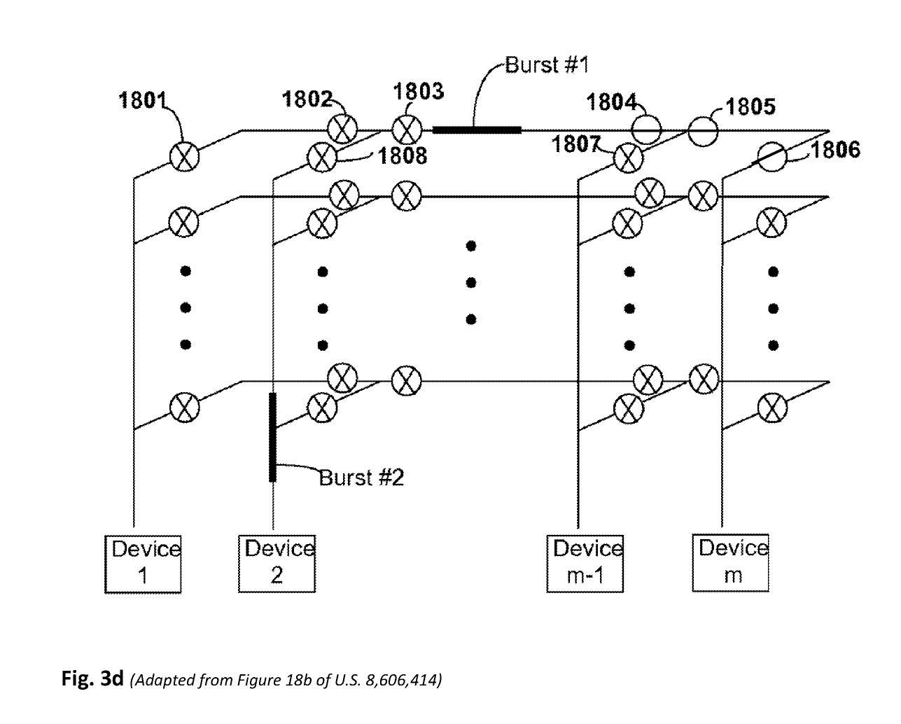

FIG. 3a, adapted from FIG. 14 of U.S. Pat. Nos. 8,032,258 and 8,606,414, depicts simple example contiguous flow transport through a simple example transport bus for microfluidic and other applications; the depicted fluidic flow (signified with superimposed heavy line) is enabled by the two open valves at the top of the figure, one of these valves connecting the second-to-left vertical conduit with the top horizontal tapped bus conduit, and the other of these valves connecting the second-to-right vertical conduit with the same top horizontal tapped bus conduit. Note the many passive “T”-topology junctions throughout the simple example microfluidic bus system.

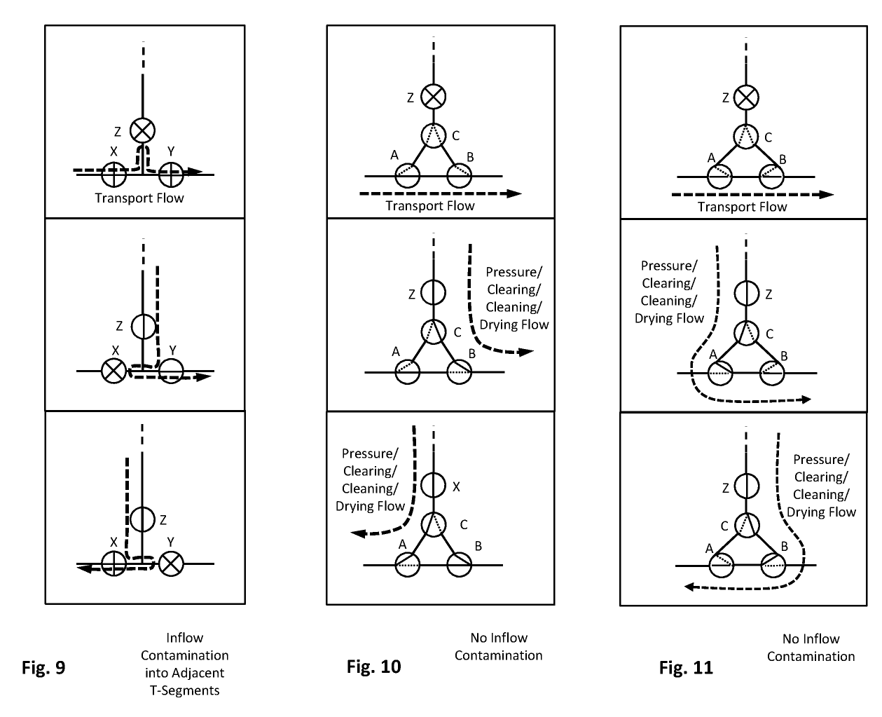

FIG. 3b, adapted from FIG. 9d of U.S. Pat. Nos. 8,032,258 and 8,606,414, depicts example contamination processes (signified with superimposed dashed heavy lines) resultant from the fluid flow (signified with superimposed heavy line) depicted in FIG. 3a.

In a preliminary approach to limit the geometric scope of such contamination processes, FIG. 3c, adapted from FIG. 9a of U.S. Pat. Nos. 8,032,258 and 8,606,414, depicts an example enhanced variation of the chemical transport bus of FIG. 3a wherein additional local valves are added so as to closely surround and chaperone each “T”-topology junction with three valves, one for each conduit meeting at the 3-way junction point.

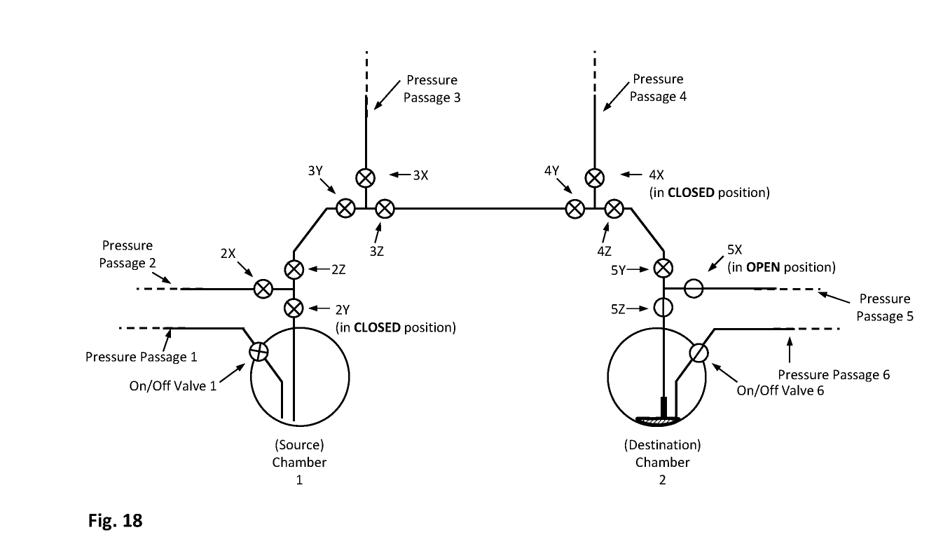

FIG. 3d, adapted from FIG. 18b of U.S. Pat. Nos. 8,032,258 and 8,606,414, depicts the example enhanced chemical transport bus depicted in FIG. 3c in the process of transporting two bursts of fluidic material which can transported through the chemical transport bus conduits, for example, by applied controlled propelling gas pressure and/or electrokinetic forces.

Many other chemical transport bus arrangements are taught in U.S. Pat. No. 8,032,258 and related patents and patent applications, and the arrangements are taught in U.S. Pat. No. 8,032,258 and related patents and patent applications can employ other valve arrangements than the examples explicitly taught therein. Additionally, U.S. Pat. No. 8,032,258 and related New Renaissance Institute patents and patent applications also teach dedicated-material, continuous gated flow, clearing, cleaning, reuse, one-time use, back-up, fault-tolerance, and other features.

Most of the approaches taught in U.S. Pat. No. 8,032,258 and related patents and patent applications, as well as the present patent application, involve choreographed and/or feedback-control of groups of valves and other entities (for example pumps), and these controlled operations can be implemented through the execution of computational algorithms.

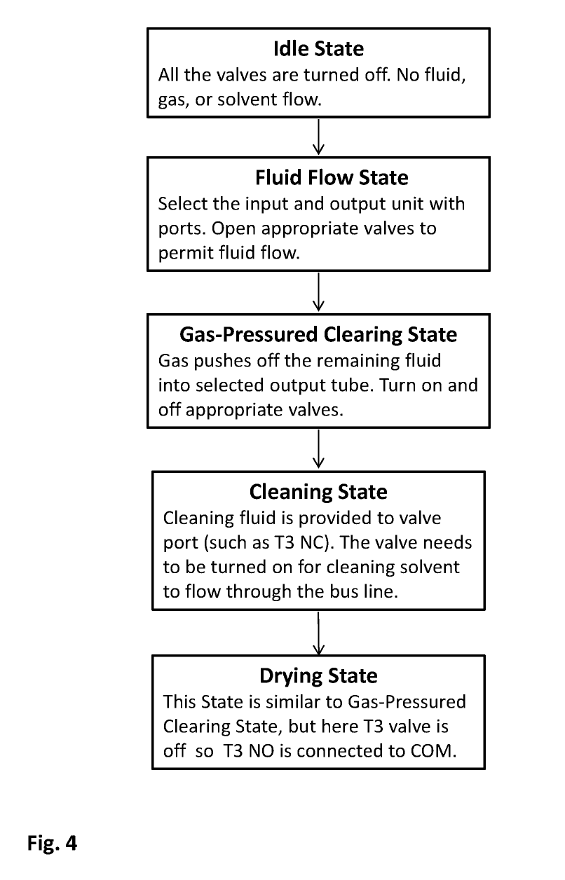

FIG. 4 depicts an example transaction-myopic system-level operation of a software controlled chemical transport bus system comprising sequences among five classes of example states:
Idle
Fluid Flow
Gas-Pressure Clearing
Solvent-Based Cleaning
Gas-Based Drying.

Such classes of states are realized by combinations of valve states (on/off, route-selection, etc.) and in some cases material locations/motions. Controlled sequences of operations among such states can be implemented through the execution of computational algorithms, the computational algorithms which in turn control the operation of valves and perhaps other entities (pumps, electrokinetic drivers, etc.).

Similarly, the example software-controlled/software-reconfigurable conduit and reaction chamber microfluidic arrangements for lab-on-a-chip and miniature chemical processing technologies depicted in FIG. 1 can, as described earlier, can comprise one or more other types of software controllable elements including gating valves, chemical/biochemical reaction chambers, pumps or other (e.g. electrokinetic) flow-drivers, mixers, thermoelectric devices, light-emitting devices (for photochemical excitation, photosensitization stimulation (for example for localized nitric-oxide donor molecules), fluorescent marker stimulation, absorption/transmission spectroscopy, colorimetric analysis, etc.), electrochemical synthesis electrodes, electrochemical (amperometry/voltammetry/coulometry) analysis electrodes, instrumentation and imaging systems, etc. Operation of such a device would similarly comprise sequences among states and/or classes of states.

### 2. CONTRIBUTIONS OF THE PRESENT INVENTION

The present invention provides a triangle-topology junction that can be used to replace and improve the performance of passive “T”-topology junction commonly employed to provide a side tap in a through-path conduit or three-conduit junction.

First, example detail of the transport of a fluid flow through a number of valve-chaperoned “T”-topology junctions such as those depicted in FIGS. 3c and 3d is provided below. However, although far more localized, there are still significant contamination processes and residual fluid pocket effects with valve-chaperoned “T”-topology junctions, and comprehensive cleaning, clearing, and drying processes can still be challenging to implement.

Accordingly, the present patent application addresses these problems and challenges with a “triangle topology” valve cluster of “single-pole double-throw” valves. Example implementations of microfluidic “single-pole double-throw” valves will be the subject of a companion New Renaissance Institute patent filing.

### 3. FLUIDIC BUS TRANSPORT ARRANGEMENTS WITH GAS-PRESSURE CLEARING, SOLVENT-BASED CLEANING, AND GAS-BASED DRYING STATES

Fluidic bus transport arrangements with gas-pressure clearing, solvent-based cleaning, and gas-based drying states are considered, discussed, and illustrated in U.S. Pat. No. 9,636,655 and U.S. patent application Ser. No. 15/499,767. In these disclosures:
“Contiguous-flow” can signify a fluid flow from one source to at least one destination that is simply started and stopped with no intervening gas or air introduced to create segmenting open gaps in the fluid flow. It is possible to modify the definition of “contiguous-flow” in various ways to admit and/or differentiate additional minor distinctions; such alternative definitions are anticipated and provided for by the invention. (It is also possible to extend the definition of “contiguous-flow” in various ways to include and/or pertain to gas flows; such extended definitions are also anticipated and provided for by the invention.)
“Burst transport” can signify a fluid flow from one source to at least one destination wherein intervening gas or air introduced to create segmenting open gaps in the fluid flow. Typically burst transport would be used to sequentially transport multiple types of fluids through the same conduit, valve, pump, etc. It is possible to modify the definition of “contiguous-flow” in various ways to admit and/or differentiate additional minor distinctions; such alternative definitions are anticipated and provided for by the invention. (It is also possible to extend the definition of “burst transport” in various ways to include and/or pertain to gas flows; such extended definitions are also anticipated provided for by the invention.)

Additionally, fluidic bus transport arrangements with gas-pressure clearing, solvent-based cleaning, and gas-based drying states have been presented for example in the present inventor's U.S. Pat. Nos. 8,032,258; 8,594,848; 8,606,414; 8,812,163; and 9,636,655. Both continuous flow and burst flow are considered in these.

At least three types of approaches could be used to improve the contamination performance and clearing, cleaning, and drying capabilities of passive “T”-topology taps/junctions:
Adding local on/off valves to chaperone each port passive “T”-topology taps/junction;

this is presented with detailed examples of use and operation in other sections of this document.
Use of a single SPDT valve in place of passive “T”-topology taps/junction for restricted applications; only a few specialized arrangements can benefit from this approach so details are not discussed.
Use of this patent application's innovative “triangle”-topology valve cluster (or functional equivalents to it) in place of passive “T”-topology taps/junction for broad general and bidirectional applications and detailed examples of use and operation are presented in other sections of this document.

The following remarks apply to this section and subsequent portions of the present patent application:
The widely adopted conventions of Normally Closed (NC) and Normally Open (NO) for Single Pole Double Throw (SPDT) valves is unfortunately opposite that of SPDT electrical switches and relays. This is likely because for fluids and gases a “closed” valve blocks flow from occurring while an “open” valve permits flow to occur; in contrast for electricity, a “closed” electrical switch permits current flow while an “open” electrical switch blocks (actually interrupts) electrical current flow from occurring.
Specifically, for SPDT valves:
   When no electricity is applied to a SPDT valve (“off” or “non-energized”), the valve is said to be “off” and in this mode provide a flow path connecting the COM and NO ports of the valve.
   When electricity is applied to a SPDT valve (“on” or “energized”), the valve is said to be on connecting the COM and NC valves.

That said, uniformity with an electrical switch analogy is tempting to employ for the sake of conformity, and the reader should be aware that some technical literature and some products could choose to adopt an electrical switch analogy instead of the conventions described above.

### 4. VALVE-CHAPERONED T-TOPOLOGY JUNCTION AND TRIANGLE-TOPOLOGY VALVE-CLUSTER IMPLEMENTATIONS AND OPERATIONS

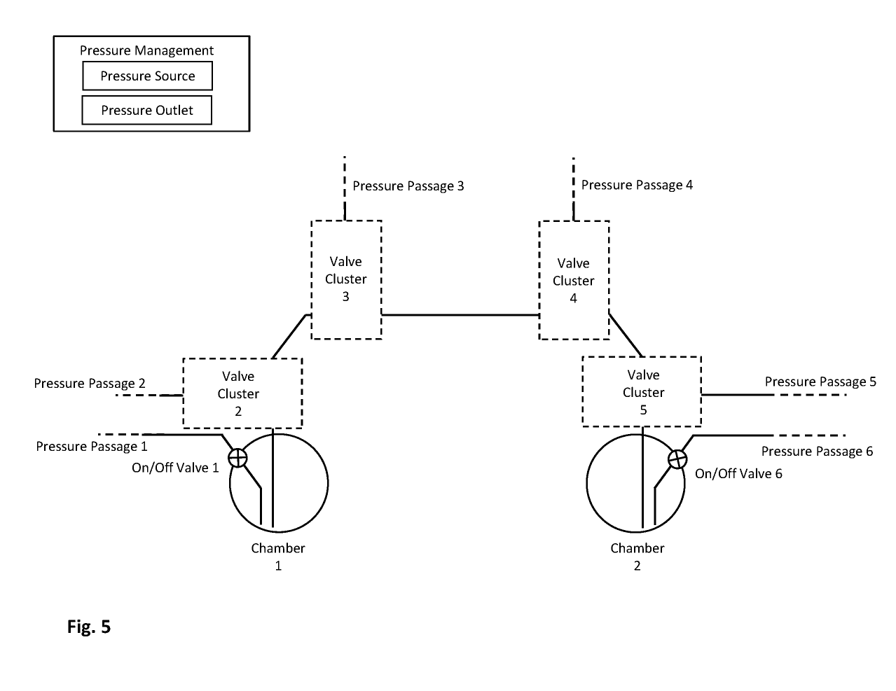

FIG. 5 depicts a simplified example system comprising two chambers, each chamber comprising a dedicated valve-gated pressure passage and a fluid transport port. The fluid transport ports of the two chambers are joined by an interconnecting transport line punctuated with valve-cluster arrangements for routing fluids and introducing gas pressure, venting, vacuum, etc.

Depending on the type of valve cluster, the intervening valve-cluster arrangements can perform at least some or all of several types of functions, and/or serve to represent functional entities including the following:
The intervening valve-cluster arrangements can be or can represent intervening taps on a microfluidic bus;
The intervening valve-cluster arrangements can serve as transfer points for applying gas pressure for propelling a fluid through valves and conduits. Since gas compresses, long transmission paths require increasing amounts of gas pumping and can slow down the rate of transfer;
The intervening valve-cluster arrangements can also be used to introduce clearing gases, cleaning solvent, and drying gases useful for reusable, reconfigurable, and/or decontamination of recyclable or safe-disposal microfluidic devices;
As will be shown, the intervening valve-cluster arrangements can be used to return unused materials abandoned in conduits and valve passages along a transmission path back to their source;
As will be shown, the intervening valve-cluster arrangements can be used to create small-volume bursts of fluid.

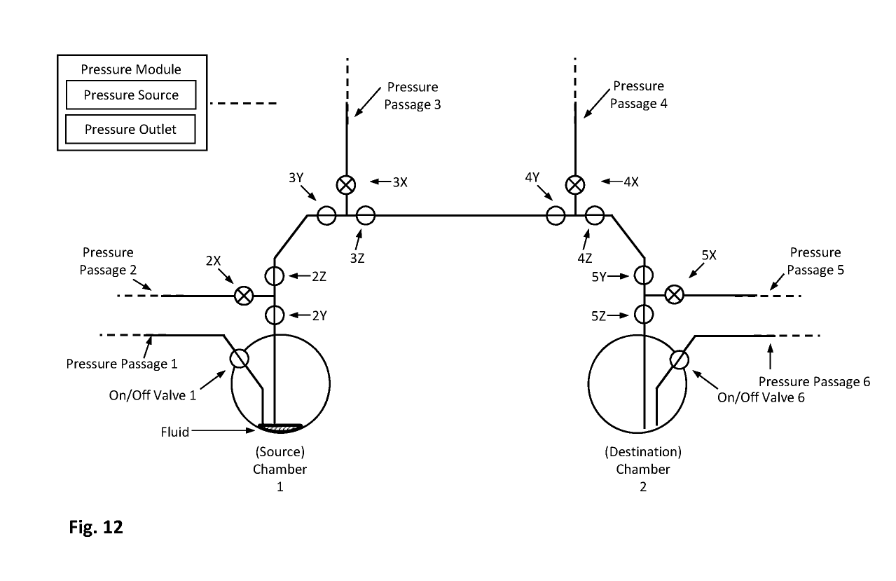

Although the example arrangement depicted in FIG. 12 comprises a total of 6 pressure passages (numbered 1 to 6), a greater or lesser number of pressure passages can be employed. The collection of valve clusters can incorporate one or multiple instances of one or more types of valve cluster(s). Each valve-gated pressure passage has a dedicated on/off gate valve (indexed with a corresponding valve number) that can be opened or closed so as to selectively introduce gas pressure, venting, vacuum, etc. into the system at selected locations and at selected times so as to obtain the type of fluid transport desired.

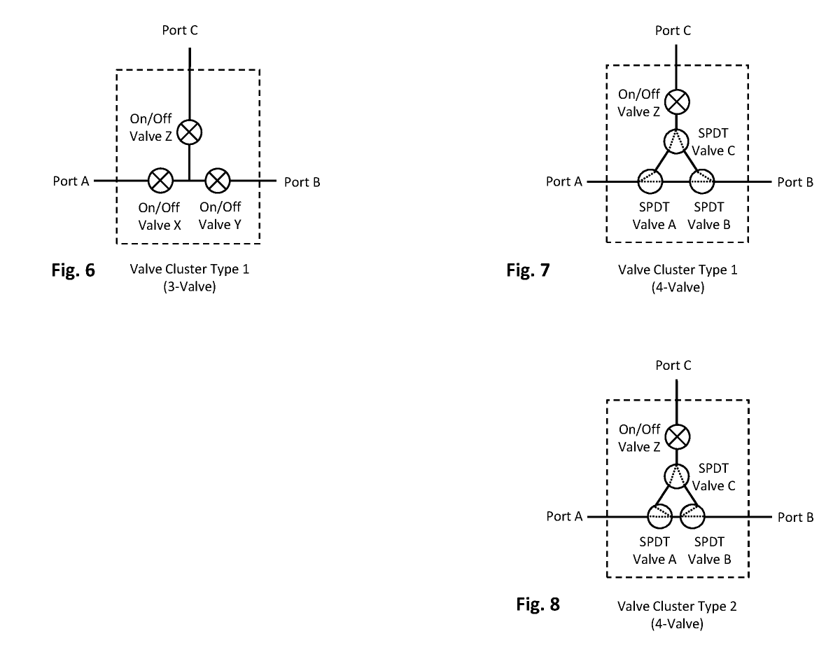

FIGS. 6-8 depict three exemplary 3-valve valve clusters (two of which include gating valves) for introducing gas pressure, venting, vacuum, etc. into the system at selected locations and at selected times so as to obtain the type of fluid transport desired.

The example arrangements shown in FIGS. 7 and 8 both depict three SPDT valves and a SPST (on/off) gate valve connected on one side to T-junction Port C and on the other side to the COM port of one of the SPDT valves. The remaining two SPDT valves are connected together by one port, and additionally connected to a dedicated port of the first SPDT valve, and to external ports (T-junction Port A for one of the remaining two SPDT valves and T-junction Port B for the other of the remaining two SPDT valves). Specifically, the COM port of one of the remaining two SPDT valves connects to T-junction Port A and the COM port of the other of the remaining two SPDT valves connects to T-junction Port B. In one example mode of operation, T-junction Port A connects directly to T-junction Port B—this can be used for example to support a standard flow path through a fluidic system. In a second example mode of operation, T-junction Port C can be used to introduce or receive a flow of clearing gas, cleaning solvent, drying gas, and/or other materials by permitting flows between T-junction Port C and T-junction Port A. In a third example mode of operation, T-junction Port C can be used to introduce or receive a flow of clearing gas, cleaning solvent, drying gas, and/or other materials by permitting flows between T-junction Port C and T-junction Port B. In a fourth example mode of operation, flows among T-junction Ports A, B, and C are blocked.

The example “triangle”-topology valve-cluster arrangement shown in FIG. 7 comprises having T-junction Port A connected to the COM port of its associated SPDT valve and having T-junction Port B connected to the COM port of its associated SPDT valve.

The example “triangle”-topology valve-cluster arrangement shown in FIG. 8 depicts a variation on example arrangement shown in FIG. 7 comprising having the COM port of the SPDT valve associated with T-junction Port A connected to the COM port of the SPDT valve associated with T-junction Port B; effectively the orientation of the “common” port of two of the SPDT valves are flipped from that of FIG. 7.

The example valve-chaperoned “T”-topology arrangement shown in FIG. 6 depicts three SPST (on/off) gate valves connected on one side to an associated T-junction port (T-junction Port A, T-junction Port, B, and T-junction Port C respectively) and on the other side to a flow T-junction.

FIGS. 9-11 illustrate example transport flow, clearing/cleaning flow, and residue/contamination scenarios, respectively, each associated with the example arrangements shown in FIGS. 6, 7, and 8.

The example arrangement shown in FIG. 9 illustrates an example transport flow (top drawing), an example clearing/cleaning flow among Port C and Port B (middle drawing), and an example clearing/cleaning flow among Port C and Port A (bottom drawing) for the example arrangement of FIG. 6. Note that the flow T-juncture inherently retains residual flows in each of the transport flow (top drawing), an example clearing/cleaning flow among Port C and Port B (middle drawing), and an example clearing/cleaning/drying flow among Port C and Port A (bottom drawing).

The example arrangement shown in FIG. 10 illustrates an example transport flow (top drawing), an example clearing/cleaning gas or solvent flow between Port C and Port B (middle drawing), and an example clearing/cleaning gas or solvent flow between Port C and Port A (bottom drawing) for the example arrangement of FIG. 7. Note that any material left in the interconnection passage between Port A and Port B from an earlier transport flow cannot be cleared, cleaned, and dried.

The example arrangement shown in FIG. 11 illustrates an example transport flow (top drawing), an example clearing/cleaning gas or solvent flow between Port C and Port B (middle drawing), and an example clearing/cleaning gas or solvent flow between Port C and Port A (bottom drawing) for the example arrangement of FIG. 8. Here that any material left in the interconnection passage between Port A and Port B from an earlier transport flow is inherently cleared, cleaned, and dried.

Accordingly, the example “triangle”-topology valve-cluster arrangement shown in FIG. 8 is advantageous over the example arrangements shown in FIGS. 6 and 7 with respect to both preventing contamination as well as clearing, cleaning, and drying.

### 5. EXAMPLE VALVE-CHAPERONED “T”-TOPOLOGY IMPLEMENTATIONS AND OPERATIONS

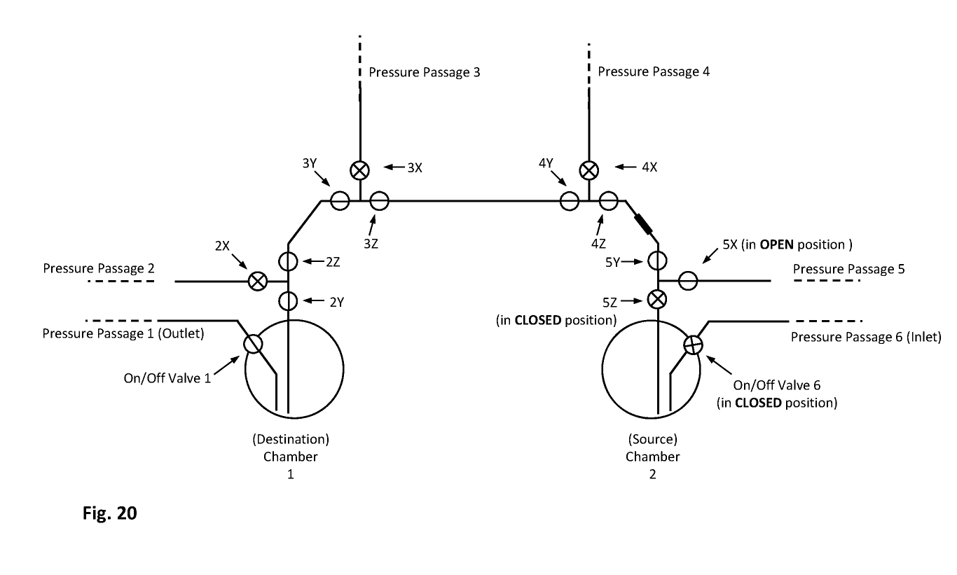

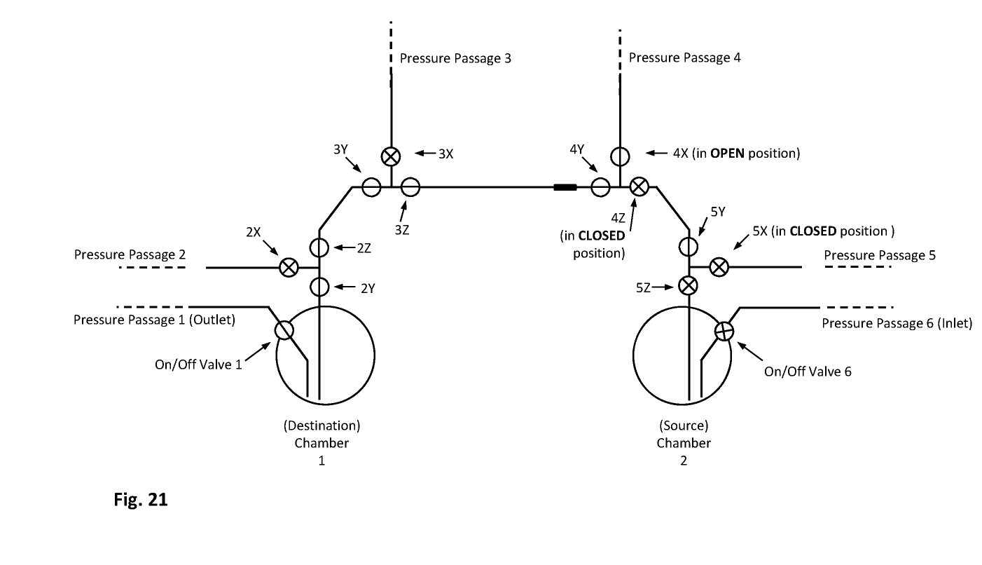

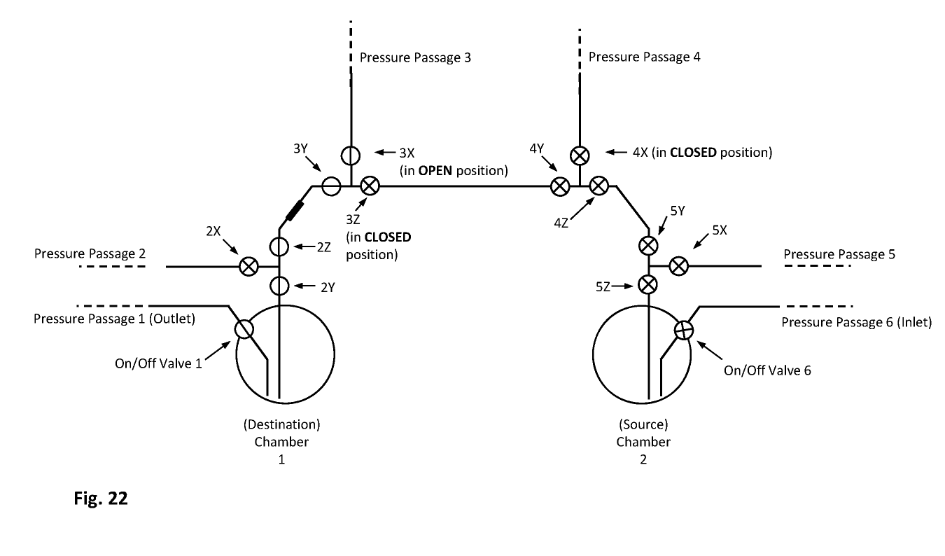

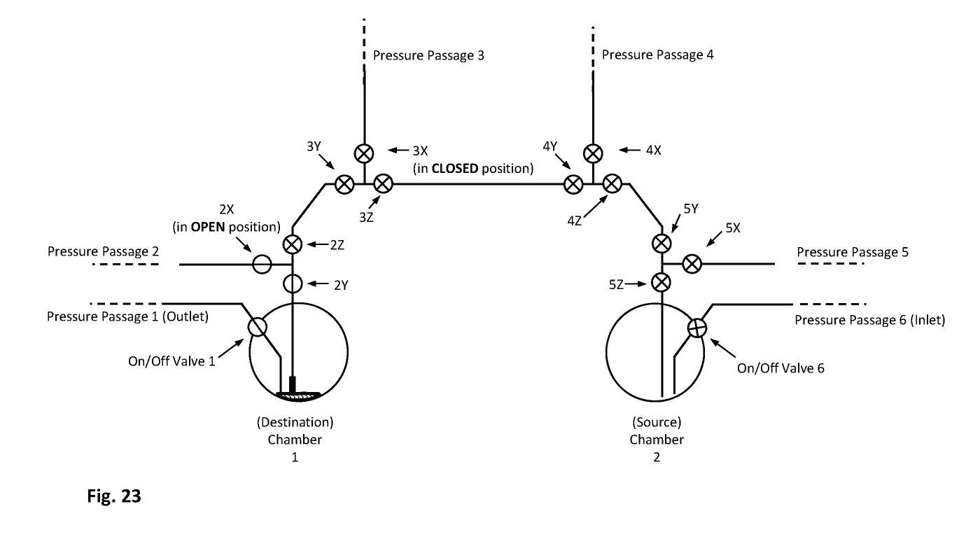

FIGS. 12-23 depict example structures and operations of an example valve-chaperoned “T”-topology implementation, incorporating multiple instances of the valve cluster depicted in FIG. 6 into the configuration depicted in FIG. 5.

FIG. 12 depicts a simplified example system comprising two chambers, each comprising a dedicated valve-gated pressure passage and a fluid transport port, and further incorporating multiple instances of the valve cluster depicted in FIG. 6 into the configuration depicted in FIG. 5; FIG. 12 further depicts an example initial situation where a fluid present in chamber 1. In this example chamber 1 can be regarded as the fluid source.

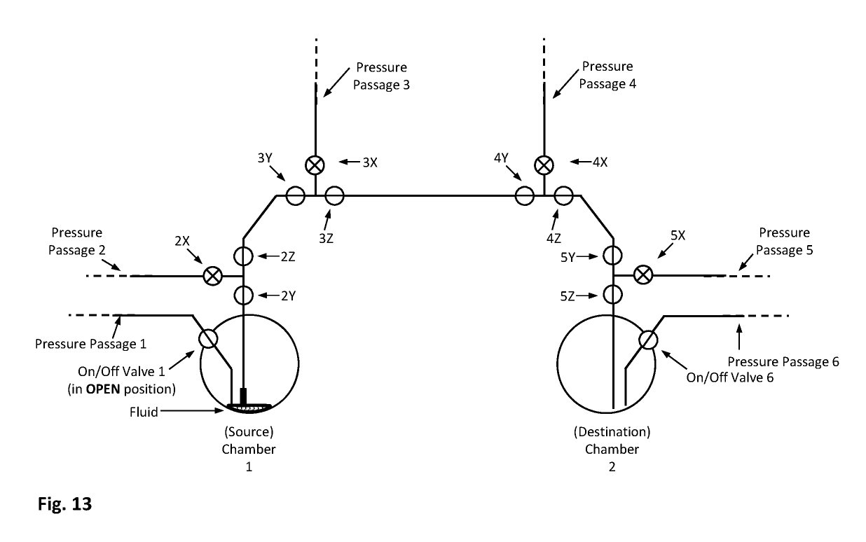

FIG. 13 depicts an example situation where gas pressure provided by pressure passage 1 going through the gas-pressure gating valve 1 powered now into an open position, resulting in pushing a fluid front into the outgoing conduit. Valves 2Y, 2Z, 3Y, 3Z, 4Y, 4Z, 5Z, and pressure passage 6 valves are open to vent the displaced gas ahead of the fluid front out of Chamber 2 through pressure passage 6.

FIG. 14 depicts an example situation where gas pressure provided by pressure passage 1 further pushing a fluid front into valve cluster 2 (comprising valves 2X, 2Y, 2Z), wherein flow valves 2Y and 2Z are open and gas-pressure gating valve 2X remains closed as it was in FIGS. 12 and 13. Valves 3Y, 3Z, 4Y, 4Z, 5Z, and pressure passage 6 valves are open to vent the displaced gas ahead of the fluid front out of Chamber 2 through pressure passage 6.

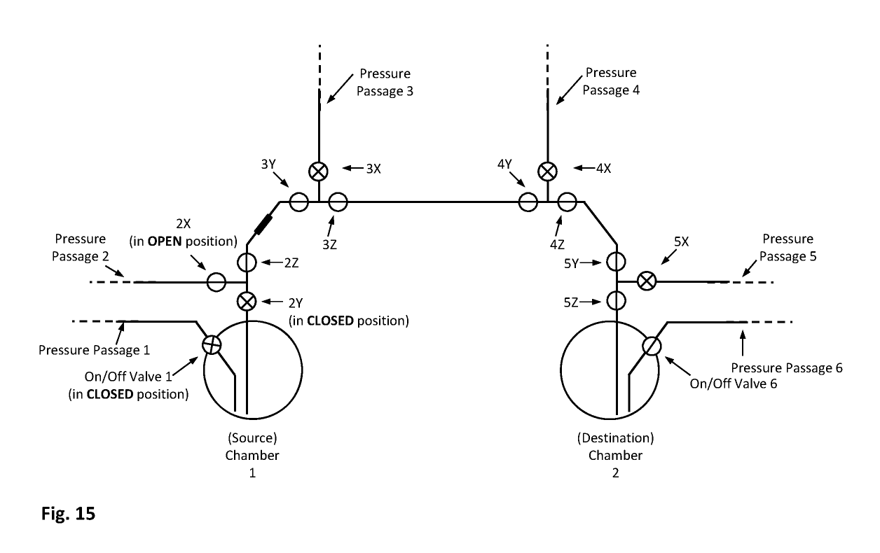

FIG. 15 depicts an example situation where the pressure passage valve 1 closed and pressure passage valve 2X open, letting the pressure passage 2 open, further pushing a fluid front past valve cluster 2 approaching valve 3Y. Valves 3Y, 3Z, 4Y, 4Z, 5Z, and pressure passage 6 valves are open to vent the displaced gas ahead of the fluid front out of Chamber 2 through pressure passage 6.

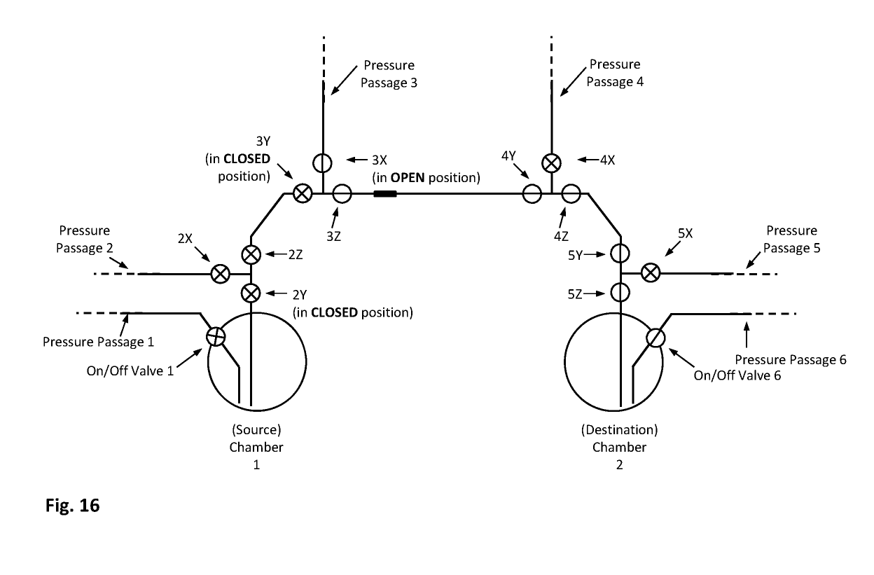

FIG. 16 depicts an example subsequent situation where gas pressure passage valve 2X and flow valve 3Y are closed and valve 3X is open allowing gas pressure from pressure passage 3 to travel past valve 3Z. Valves 4Y, 4Z, 5Z, and pressure passage 6 valves are open to vent the displaced gas ahead of the fluid front out of Chamber 2 through pressure passage 6.

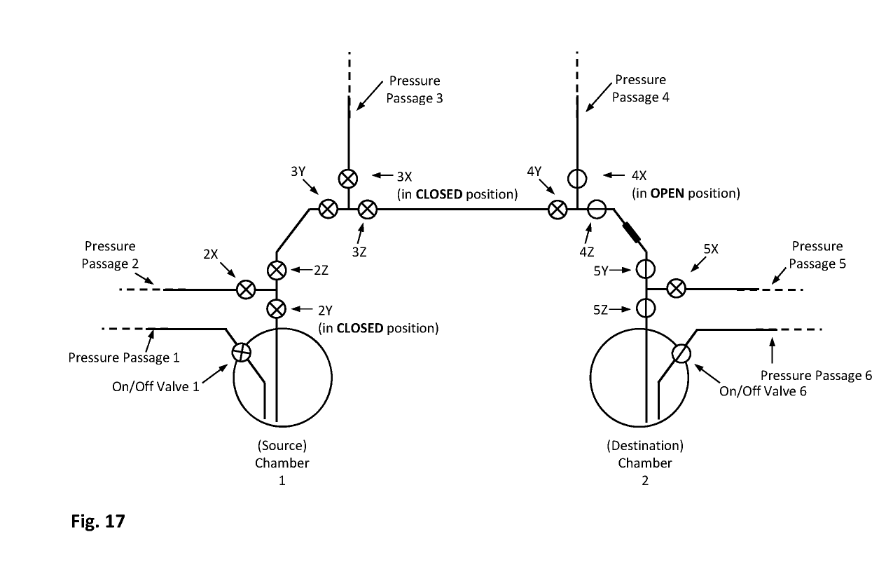

FIG. 17 depicts an example situation where gas pressure passage valve 3X is closed and gas pressure passage valve 4X is open allowing the pressure from gas pressure passage 4 to transport fluid through valve 4Z, pushing the fluid towards valve 5Y. Valves 5Z and pressure passage 6 valves are open to vent the displaced gas ahead of the fluid front out of Chamber 2 through pressure passage 6.

FIG. 18 depicts an example situation where gas pressure passage valve 4X closed and gas pressure passage valve 5X is open allowing the pressure from pressure passage 5 to push the fluid front past valve 5Z into chamber 2 (the destination).

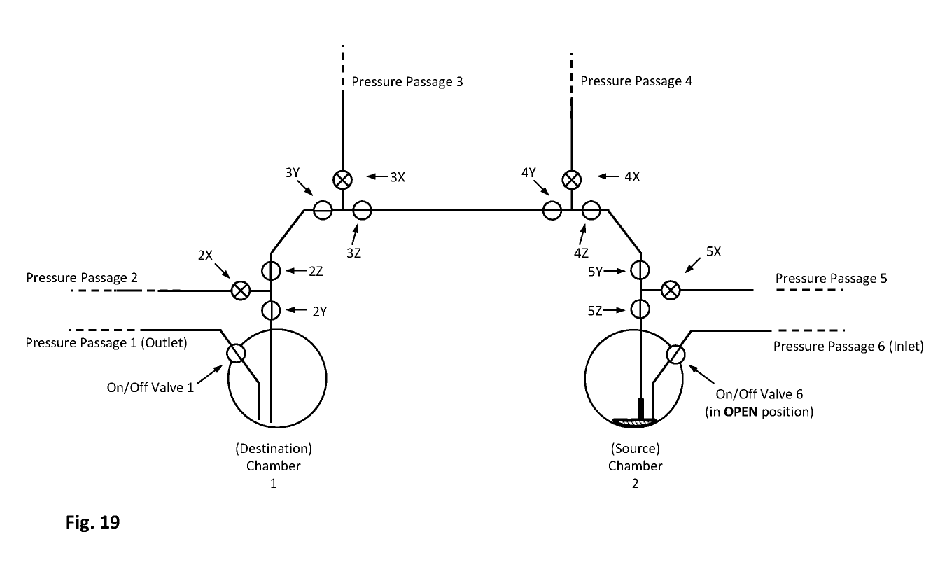

FIGS. 19-23 depict similar example operation steps for the same arrangement that result in a flow travelling in the opposite direction, employing chamber 2 as the source and chamber 1 as the destination.

Alternatively, the sequences described above can be modified so that pressure passage 6 provides a vacuum draw at chamber 2, drawing fluid into chamber 2 from chamber 1 through the transport line with pressure passages 1 through 5 sequentially providing incoming-pressure venting.

Alternatively, the sequences described above can be modified so that is applied as presented in the example and additionally pressure passage 6 provides a vacuum draw at chamber 2, drawing fluid into chamber 2 from chamber 1 through the transport line with pressure passages 1 through 5 sequentially providing incoming-pressure.

### 6. EXAMPLE TRIANGULAR-TOPOLOGY VALVE-CLUSTER IMPLEMENTATIONS AND OPERATIONS

As mentioned previously, the triangle-topology valve-cluster provides a better contamination performance and better facilitates various types of clearing, cleaning, and drying capabilities than simple passive “T”-topology junctions or valve-chaperoned “T”-topology junctions.

In this section, example operation and features are presented for the example valve-chaperoned “T”-topology implementation, incorporating multiple instances of the valve cluster depicted in FIG. 8 into the configuration depicted in FIG. 5.

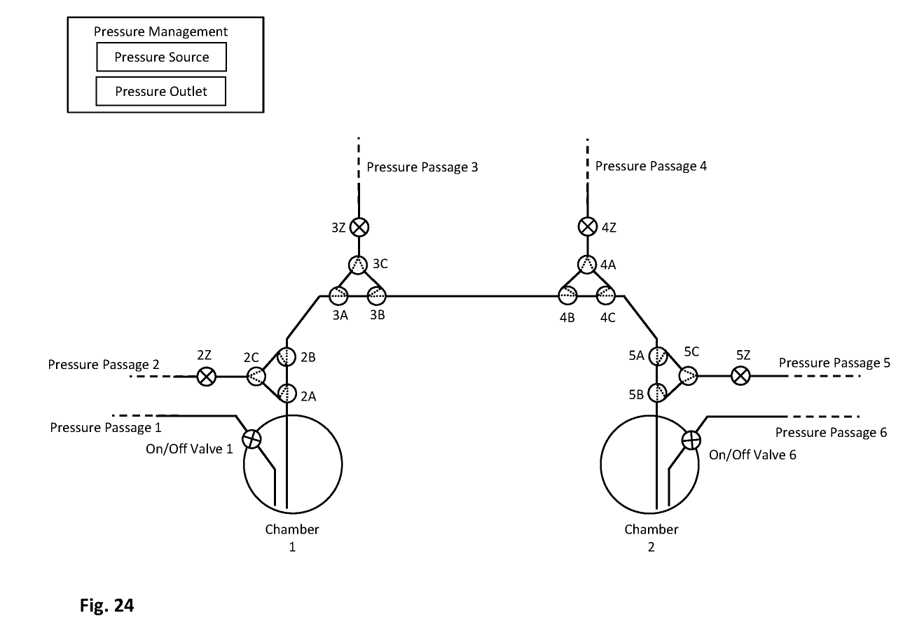

FIG. 24 depicts a simplified example system comprising two chambers, each comprising a dedicated valve-gated pressure passage and a fluid transport port, and further incorporating multiple instances of the valve cluster depicted in FIG. 8 into the configuration depicted in FIG. 5. The fluid transport ports of the two chambers are joined by an interconnecting transport line punctuated with the valve cluster arrangement depicted in FIG. 8 for routing fluids and introducing gas pressure, venting, vacuum, etc. Although the example arrangement depicted in FIG. 24 comprises a total of 6 pressure passages (numbered 1 to 6), a greater or fewer number can be used. Each pressure passage has a dedicated on/off gate valve (indexed with a corresponding valve number) that can be opened or closed so as to selectively introducing gas pressure, venting, vacuum, etc. into the system at selected locations and at selected times so as to obtain the type of fluid transport desired. Pressure passages 2 to 5 attach through gating gas pressure providing valves (2Z, 3Z, 4Z, 5Z) within four different triangle-topology valve-clusters comprising three SPDT valves. One triangle valve cluster comprises the set of SPDT valves {2A,2B,2C}, another triangle valve cluster comprises the set of SPDT valves {3A,3B,3C}, another triangle valve cluster comprises the set of SPDT valves {4A,4B,4C}, and the final depicted triangle valve cluster comprises the set of SPDT valves {5A,5B,5C}. In the figure. the three valves in the valve cluster are drawn in an arrangement which, at the proper time, permit a propelling gas pressure to flow through each depicted triangle-topology in a counterclockwise manner as the fluid front is moved from Chamber 1 to Chamber 2. Although other venting arrangements are possible, in this example pressure passage 6 valve is open so as to vent the displaced gas ahead of the fluid front out of Chamber 2 through pressure passage 6.

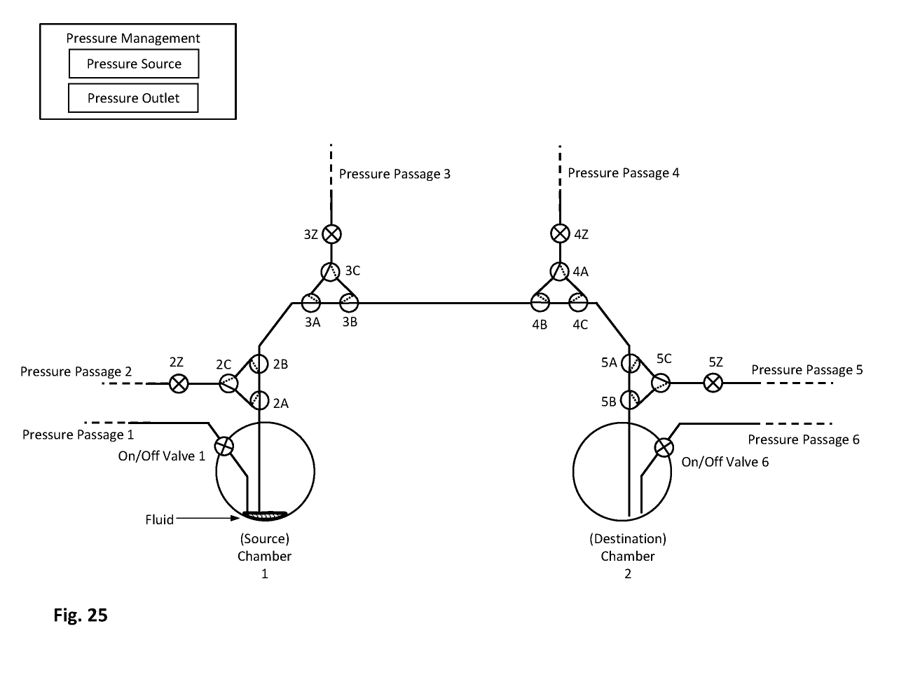

FIG. 25 depicts an example initial situation where a volume of fluid present is in chamber 1. In this example chamber 1 can be regarded as the fluid source. In the example initial situation, all the valves connecting the outside pressure exchanges (gas sources, or as later described venting and/or vacuum) to pressure passage 1 through 6 are closed. As an example additional preparatory step illustrated in this example, the valves (2C, 3C, 4C, 5C) to be involved in anticipated future steps of propelling of the fluid by gas pressure applied by its associated valve cluster are put in the proper valve-state to do so. As an additional example preparatory step illustrated in this example, valves within the triangle valve clusters that are to be involved in the anticipated fluid transport (2A, 2B, 3A, 3B, 4A, 4B, 5A, and 5B) are put into valve-states that provide a direct path between Chamber 1 and Chamber 2. Although other venting arrangements are possible, in this example pressure passage 6 valve is open so as to vent the displaced gas ahead of the fluid front out of Chamber 2 through pressure passage 6.

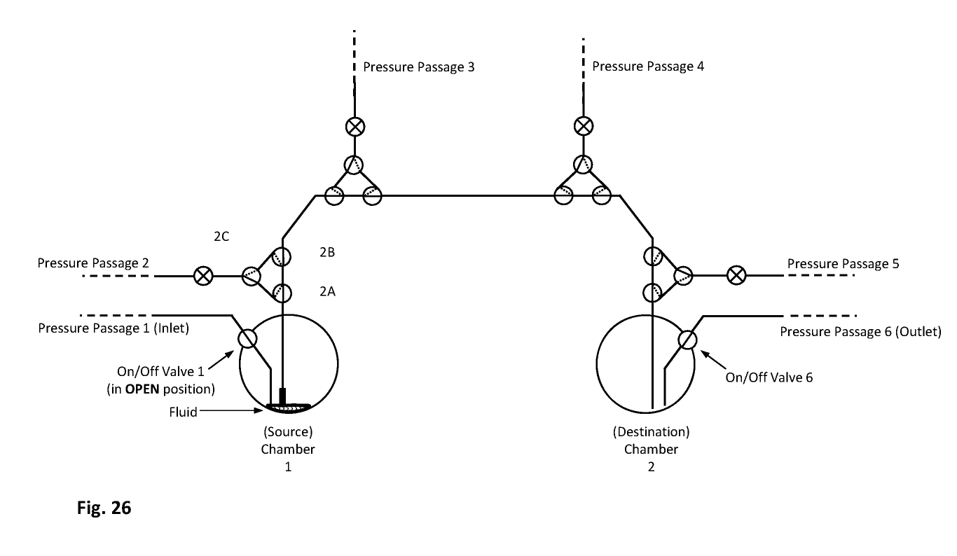

FIG. 26 depicts gas pressure provided by pressure passage 1 going through the gas-pressure gating valve 1 powered now into an open position. The pressure coming from passage 1 pushes the fluid through the depicted conduit on a path to exit from Chamber 1. Although other venting arrangements are possible (for example, using one or more of pressure passages in the triangle valve clusters), in this example (as described above) valves within the triangle valve clusters are pre-staged to create a transport passage from Chamber 1 to Chamber 2, and so leveraging this the gas-pressure gating valve 6 is opened so that pressure passage 6 attaching to Chamber 2 permits outgoing-pressure venting for gas in the system ahead of the fluid front that is pushed into Chamber 2 as the fluid moves through the transport passage.

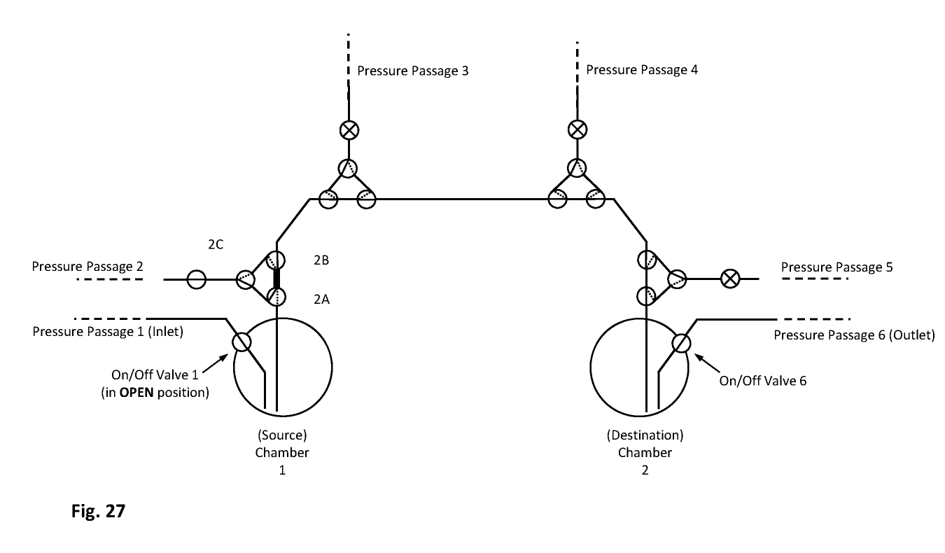

FIG. 27 depicts the pressure passage valve 1 closed and pressure passage valve 2 open so as to introduce gas pressure from gas pressure passage 2 enter the first-encountered triangle valve cluster through valve 2C. As depicted, this requires valve 2A to change valve state from the state it depicted in FIG. 26 so as to provide pressure from pressure passage 2 that is available through valve 2C. The gas pressure from pressure passage 2 is provide through valves 2C and into valve 2C pushes the fluid tail from 2A into and through valve 2B pushing, the fluid further on its way to Chamber 2 through the transport passage through valves 3A, 3B, 4A, 4B, 5A, and 5B. Additionally, in this example, the gating pressure passage valve for pressure passage 1 has been closed. Further, although other venting arrangements are possible, in this example pressure passage 6 valve is open so as to vent the displaced gas ahead of the fluid front out of Chamber 2 through pressure passage 6.

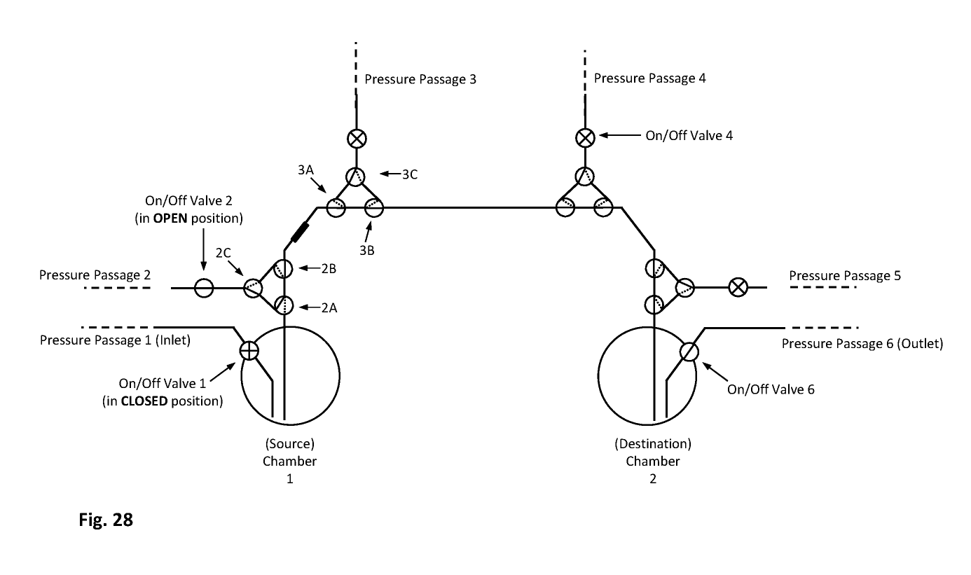

FIG. 28 depicts the fluid front traveling beyond valve 2B and approaching valve 3A, now propelled with gas pressure provided from pressure passage 2 rather than pressure passage 1. Although other venting arrangements are possible, in this example pressure passage 6 valve is open so as to vent the displaced gas ahead of the fluid front out of Chamber 2 through pressure passage 6.

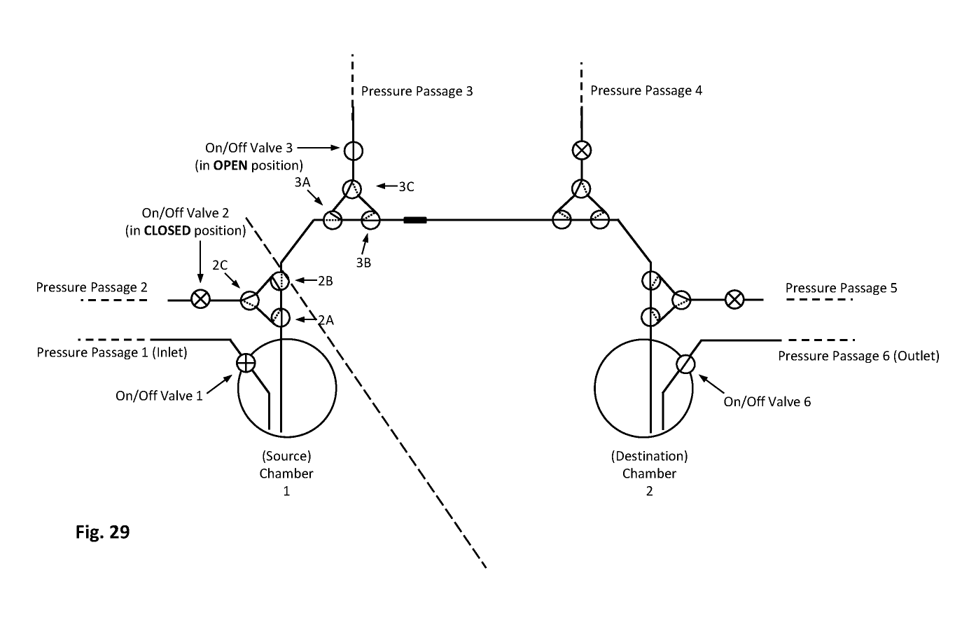

FIG. 29 depicts a subsequent step where the first-encountered triangle valve cluster (comprising valves 2A, 2B, and 2C) no longer provides gas pressure from pressure passage 2 to transport the fluid towards Chamber 2, and instead the next-encountered triangle valve cluster (comprising valves 3A, 3B, and 3C) provides gas pressure from pressure passage 3 to transport the fluid towards Chamber 2. As depicted, this requires valve 3A to change valve state from the state it depicted in FIG. 28 so as to provide pressure from pressure passage 3 that is available through valve 3C. Although other venting arrangements are possible, in this example pressure passage 6 valve is open so as to vent the displaced gas ahead of the fluid front out of Chamber 2 through pressure passage 6.

Further as to FIG. 29, the status of operation of arrangement of FIG. 24 can now be regarded as being functionally portioned as suggested by the long dashed dividing line tangent to valve 2B. At this point in the transport process, affairs to right and above the long dashed dividing line are still involved with the transport of the fluid towards Chamber 2, while affairs to left and below the long dashed dividing line are no longer involved with the transport of the fluid towards Chamber 2. As far as the transport task is concerned, the state of the valves can remain or be assigned any valve state. One example possible choice would be to power off all the valves so as to conserve electrical power. Another example possible choice would be to leave each valve in the state it was last changed to—this will be illustrated as port of the reverse-direction flow to be considered shortly. Yet another possible choice would be to actively start some sort of beneficial process, for example returning any unused fluid back into Chamber 1, or to invoke a clearing/cleaning/drying sequence. For sake of illustration, the state of valves 2A, 2B, and 2C will be set in an example configuration to returning any unused fluid between valve 2B and Chamber 1 back into Chamber 1. (It is noted that a clearing/cleaning/drying sequence where potentially contaminated unused fluid between valve 2B and Chamber 1 is removed from the system, additional valve arrangements can or must be advantageously added.)

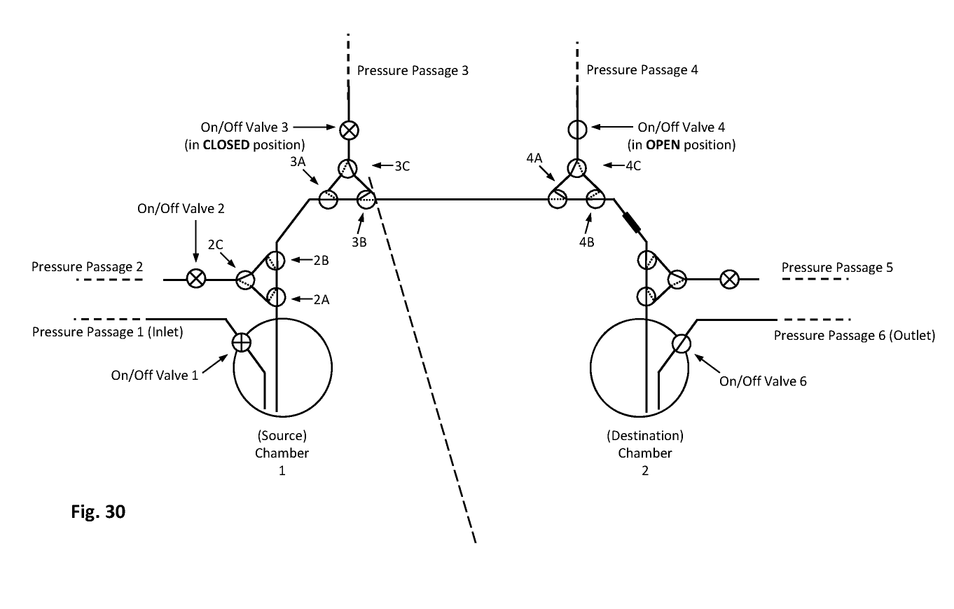

FIG. 30 depicts a subsequent step where the previously-encountered triangle valve cluster (comprising valves 3A, 3B, and 3C) no longer provides gas pressure from pressure passage 3 to transport the fluid towards Chamber 2, and instead the next-encountered triangle valve cluster (comprising valves 4A, 4B, and 4C) provides gas pressure from pressure passage 4 to transport the fluid towards Chamber 2. As depicted, this requires valve 4A to change valve state from the state it depicted in FIG. 29 so as to provide pressure from pressure passage 4 that is available through valve 4C. Although other venting arrangements are possible, in this example pressure passage 6 valve is open so as to vent the displaced gas ahead of the fluid front out of Chamber 2 through pressure passage 6.

Further as to FIG. 30, the status of operation of arrangement of FIG. 24 can now be regarded as being functionally portioned as suggested by the rotated long dashed dividing line tangent to valve 3B. At this point in the transport process, affairs to right and above the long dashed dividing line are still involved with the transport of the fluid towards Chamber 2, while affairs to left and below the long dashed dividing line are no longer involved with the transport of the fluid towards Chamber 2. As before, as far as the transport task is concerned the state of the valves can remain or be assigned any valve state. The choices can again include (1) power off all the valves so as to conserve electrical power, (2) leave each valve in the state it was last changed to (as will be considered shortly), and (3) actively start some sort of beneficial process, for example returning any unused fluid back into Chamber 1, or to invoke a clearing/cleaning/drying sequence. For sake of illustration, the state of valves 2A, 2B, 2C, 3A, 3B, and 3C will be set in an example configuration to returning any unused fluid between valve 3B and Chamber 1 back into Chamber 1. (As before it is noted that a clearing/cleaning/drying sequence where potentially contaminated unused fluid between valve 3B and Chamber 1 is removed from the system, additional valve arrangements can or must be advantageously added.)

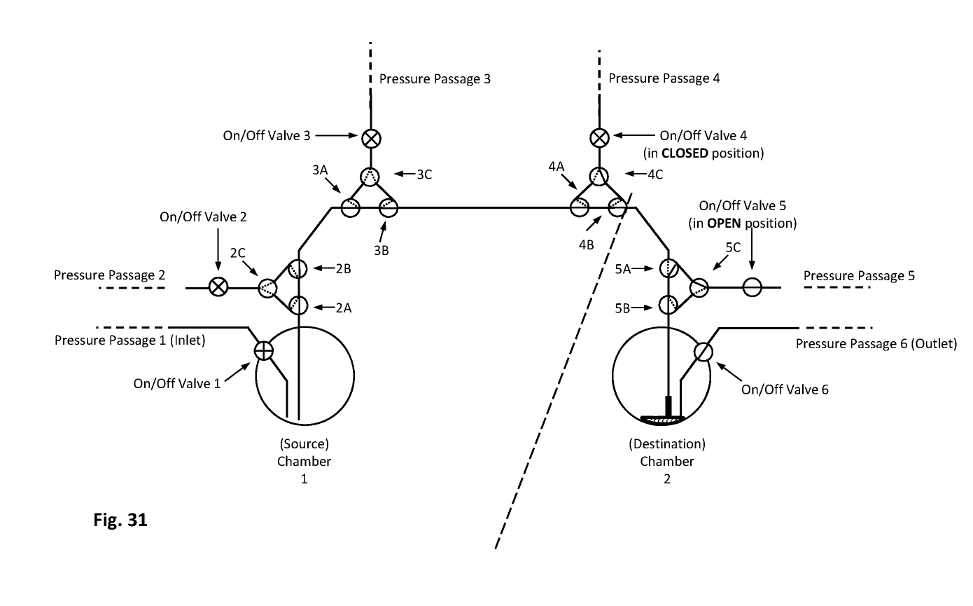

FIG. 31 depicts a subsequent step where the previously-encountered triangle valve cluster (comprising valves 4A, 4B, and 4C) no longer provides gas pressure from pressure passage 4 to transport the fluid towards Chamber 2, and instead the next-encountered triangle valve cluster (comprising valves 5A, 5B, and 5C) provides gas pressure from pressure passage 5 to transport the fluid towards Chamber 2. As depicted, this requires valve 5A to change valve state from the state it depicted in FIG. 29 so as to provide pressure from pressure passage 5 that is available through valve 5C. Although other venting arrangements are possible, in this example pressure passage 6 valve is open so as to vent the displaced gas ahead of the fluid front out of Chamber 2 through pressure passage 6.

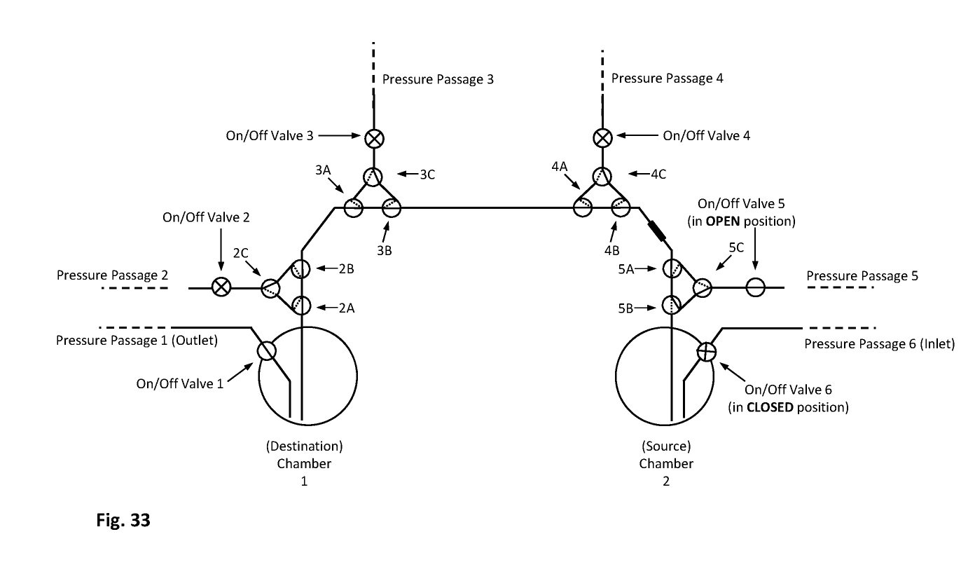

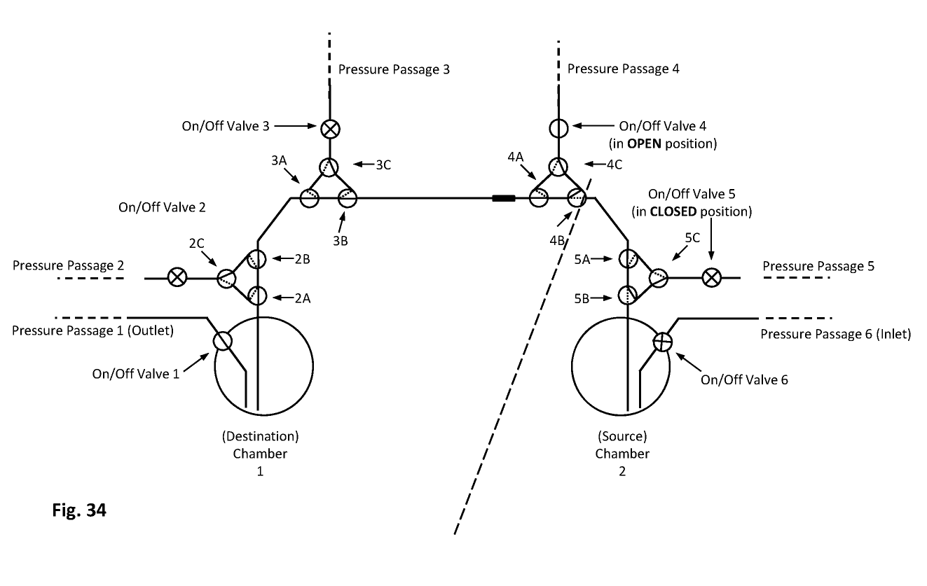

Further as to FIG. 31, the status of operation of arrangement of FIG. 24 can now be regarded as being functionally portioned as suggested by the further-rotated long dashed dividing line tangent to valve 4B. At this point in the transport process, affairs to right and above the long dashed dividing line are still involved with the transport of the fluid towards Chamber 2, while affairs to left and below the long dashed dividing line are no longer involved with the transport of the fluid towards Chamber 2. As before, as far as the transport task is concerned the state of the valves can remain or be assigned any valve state. The choices can again include (1) power off all the valves so as to conserve electrical power, (2) leave each valve in the state it was last changed to (as will be considered shortly), and (3) actively start some sort of beneficial process, for example returning any unused fluid back into Chamber 1, or to invoke a clearing/cleaning/drying sequence. For sake of an alternative illustration, for the examples depicted in FIGS. 34-36 the state of valves 2A, 2B, 2C, 3A, 3B, 3C, 4A, 4B, and 4C will be simply left in the last states that were assigned.

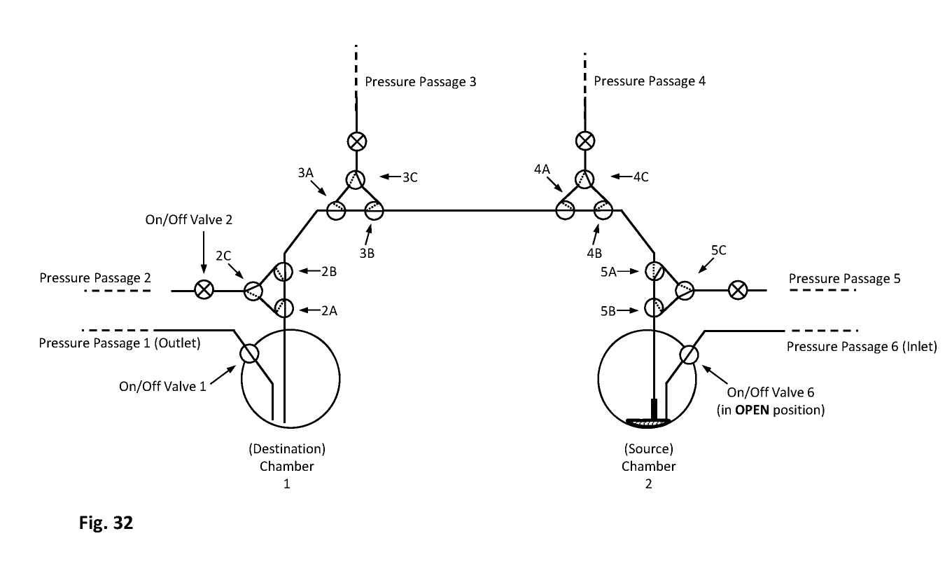

FIGS. 32-36 depict related example operation steps for the same arrangement that result in a flow travelling in the opposite direction, employing Chamber 2 as the source and Chamber 1 as the destination. Although other venting arrangements are possible, in this example pressure passage 1 valve is open so as to vent the displaced gas ahead of the fluid front out of Chamber 1 through pressure passage 1.

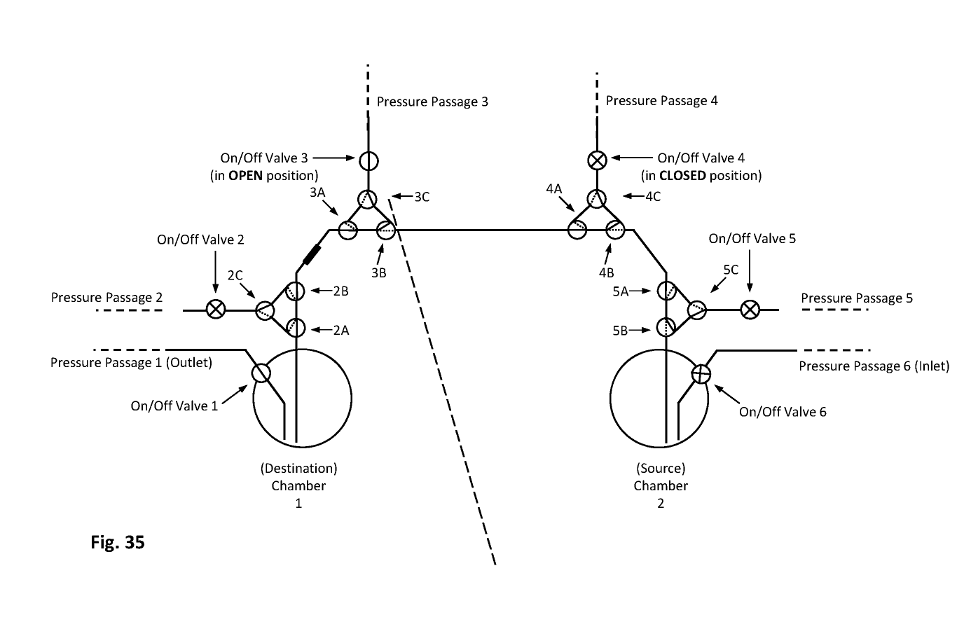

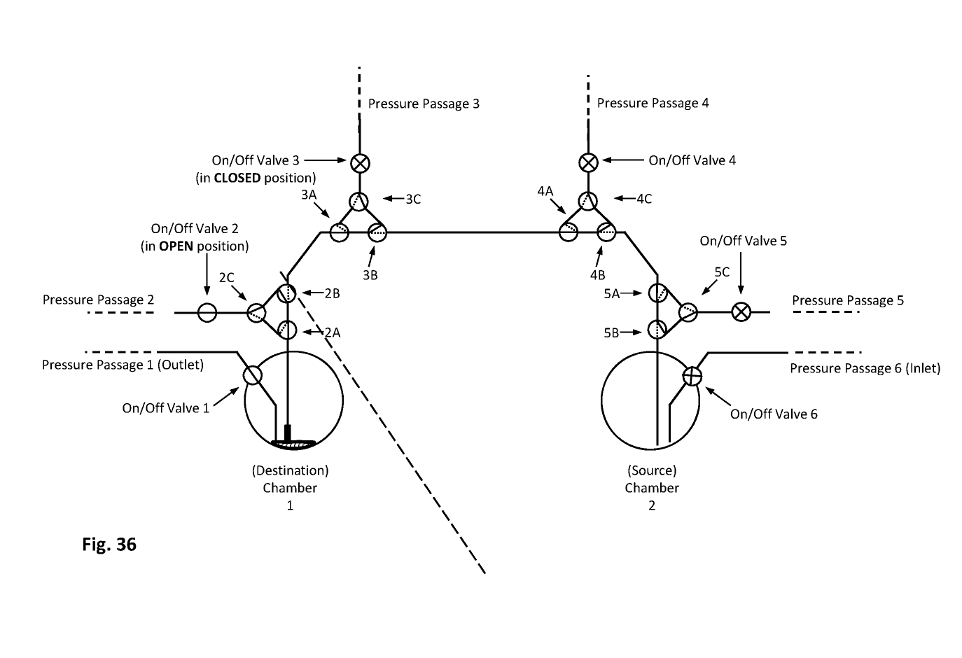

Further as to FIGS. 34-36, the status of operation of arrangement of FIG. 24 can now be regarded as being functionally portioned as suggested by the further-rotated long dashed dividing line tangent to valve 4B in FIG. 34, tangent to valve 3B in FIG. 35, and tangent to valve 2B in FIG. 36. At this point in the transport process, affairs to right and above the long dashed dividing line are still involved with the transport of the fluid towards Chamber 1, while affairs to left and below the long dashed dividing line are no longer involved with the transport of the fluid towards Chamber 1. As before, as far as the transport task is concerned the state of the valves can remain or be assigned any valve state. The choices can again include (1) power off all the valves so as to conserve electrical power, (2) leave each valve in the state it was last changed to (as will be considered shortly), and (3) actively start some sort of beneficial process, for example returning any unused fluid back into Chamber 1, or to invoke a clearing/cleaning/drying sequence.

Alternatively, the sequences described above can be modified so that pressure passage 6 provides a vacuum draw at chamber 2, drawing fluid into chamber 2 from chamber 1 through the transport line with pressure passages 1 through 5 sequentially providing incoming-pressure venting.

Alternatively, the sequences described above can be modified so that is applied as presented in the example and additionally pressure passage 6 provides a vacuum draw at chamber 2, drawing fluid into chamber 2 from chamber 1 through the transport line with pressure passages 1 through 5 sequentially providing incoming-pressure.

### 7. CLEARING, CLEANING, AND DRYING OPERATIONS USING THE TRIANGULAR-TOPOLOGY VALVE-CLUSTER

In addition to the highly-controlled bi-directional transport capabilities illustrated above in part with the examples provided in other sections of this document, as discussed in the introduction to this section the example “triangle”-topology valve-cluster arrangement of FIG. 8 and its operation (shown in the examples of FIG. 11) are advantageous over the example arrangements shown in FIGS. 6 and 7 with respect to preventing contamination as well as bi-directional clearing, cleaning, and drying.

As discussed previously, the example valve-state arrangement depicted in the top portion of FIG. 10 for the valve arrangement of FIG. 7 can provide passive bi-directional transport flow and the valve arrangement can prevent inflow contamination. Additionally:
The valve-state arrangement depicted in the middle portion of FIG. 10 shows example clearing/cleaning/drying flow delivered to the conduit to the right of valve B. However, any material left in the interconnection passage between valve A and valve B from an earlier transport flow cannot be cleared, cleaned, and dried.
The valve-state arrangement depicted in the lower portion of FIG. 10 shows example clearing/cleaning/drying flow to the conduit to the left of valve A. However, any material left in the interconnection passage between valve A and valve B from an earlier transport flow cannot be cleared, cleaned, and dried.

The example arrangement shown in FIG. 11 for the improved triangle-topology valve-cluster arrangement depicted in FIG. 8 (where the orientation of the “common” port of two of the SPDT valves are flipped from that of FIG. 10) illustrates an example transport flow (top drawing) can also provide passive bi-directional transport flow, and the valve arrangement can also prevent inflow contamination. Additionally:
The valve-state arrangement depicted in the middle portion of FIG. 11 shows example clearing/cleaning/drying flow between valve A and valve B and the conduit to the right of valve B.
The valve-state arrangement depicted in the lower portion of FIG. 11 shows example clearing/cleaning/drying flow between valve A and valve B and the conduit to the left of valve A.

Thus, any material left in the interconnection passage between valve A and valve B from an earlier transport flow is inherently cleared, cleaned, and dried employing the example triangle-topology valve-cluster arrangement of FIG. 8.

Further, by first passing a fluid flow through a triangle-topology valve-cluster arrangement of FIG. 8 and then blocking the source and subsequently propelling the tail of the fluid flow with gas pressure introduced into the third port of the triangle-topology valve-cluster (adapting the discussion associated with FIGS. 26-28), the example triangle-topology valve-cluster arrangement of FIG. 8 can be used to create small-volume fluid bursts when the fluid source is not limited as shown in some of the previous examples.

Yet further, as previously disclosed with respect to the operation of the portion of the example arrangement to the right and above the long dashed angular dividing line in FIGS. 29-31, the example triangle-topology valve-cluster arrangement of FIG. 8 also can be used to facilitate the return of materials (that had been abandoned mid-transport) in conduits back to its source. In addition to implementing a clean-up function after transport (as depicted and described in conjunction with FIGS. 29-31), this “return of materials” capability complements the creation of small-volume fluid bursts described in the preceding paragraph.

Additionally, the example triangle-topology valve-cluster arrangement of FIG. 8 can perform a number of other nuanced functions of value in complex, specialized, or high-performance microfluidic and more general types of fluidic systems.

### 8. ALTERNATIVE IMPLEMENTATIONS AND EXTENSIONS OF THE TRIANGULAR-TOPOLOGY VALVE-CLUSTER

It is anticipated that the example triangle-topology valve-cluster arrangement of FIG. 8 can be implemented or approximated in various manners and with variations.

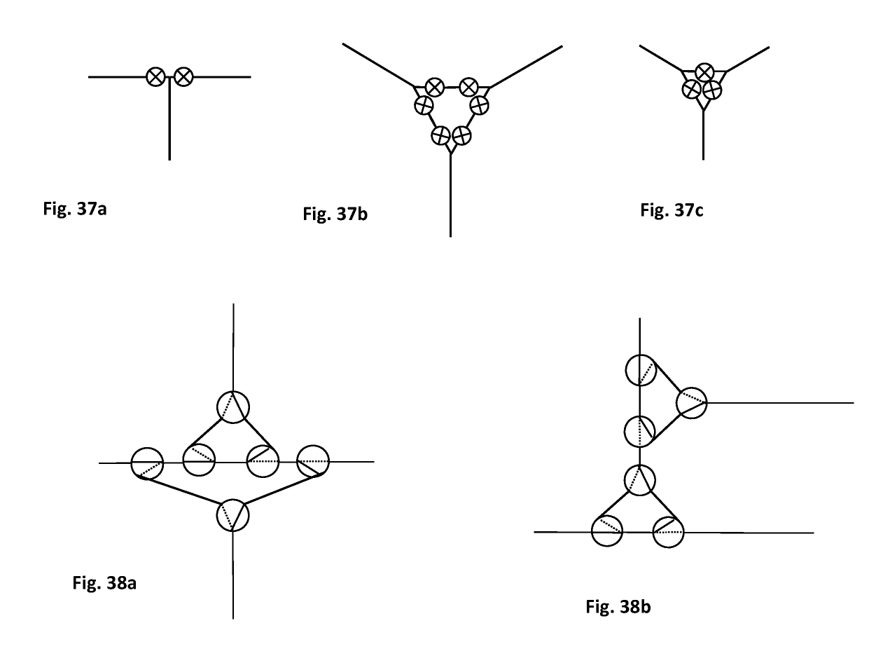

Example implementations of microfluidic “single-pole double-throw” valves will be the subject of a companion New Renaissance Institute patent filing. However, with a notable degradation of contamination performance, each SPDT valve could be “approximated” with a pair of very-closely spaced on/off valves as suggested in FIG. 37a. These could then be interconnected with the triangle-topology of FIG. 8 to render an arrangement such as that suggested by FIG. 37b—clearly there are redundant valves and the approximation could be simplified to that of FIG. 37c. It is noted the valve control logic to operate each of the three valves in the arrangement depicted in FIG. 37c could be expected to differ (via a well-defined logic transformation) from valve control logic to operate each of the three valves in the arrangement depicted in FIG. 8: for example each of the three arms in the arrangement depicted in FIG. 37c is flow-enabled by a single valve, while a corresponding arm in the arrangement depicted in FIG. 8 requires the cooperation of pairs of valves.

Additionally, it is also anticipated that the example triangle-topology valve-cluster arrangement of FIG. 8 can be extended in various manners to include additional ports for localized cleaning/clearing/drying flow insertions or implementing more complicated fluidic architecture junctions. Further, each resulting functional form can be implemented in a variety of variations. This quickly becomes a full area in itself; two four-port examples providing useful functions are depicted in FIGS. 38a and 38b. Many other arrangements and variations are possible and anticipated by the invention.

### 9. LOGIC ELECTRONICS AND CONTROL MESSAGE ARCHITECTURE FOR TRIANGULAR-TOPOLOGY VALVE-CLUSTER IMPLEMENTATIONS

Much or all of the operation of the valve systems discussed in the present patent application involve choreographed and/or feedback-control of groups of a large number of valves and other entities (for example pumps, mixers, electrically controlled photochemical reactors, etc.), and these controlled operations can be implemented through the execution of computational algorithms.

In some implementations it can be useful and most flexible to provide direct controllability of each valve, and provide each valve with its own unique address.

In other implementations it can be useful (for example faster performance, simplified programming, etc.) to provide “macro” controllability for operating groups of valves at the same time. Such “macro”-based control could be implemented in software, firmware, and/or hard-wired logic.

In yet other implementations it can be useful (for example faster performance, simplified programming, etc.) to provide “macro” controllability for operating groups of valves that involve a time-defined sequence. Such “macro”-based control could also be implemented in software, firmware, and/or hard-wired logic.

In implementations involving “macro” control it can be future useful to provide “macro” controllability for operating groups of valves, it can be useful (for example faster performance, simplified programming, etc.) to provide conditional inputs or parameters for the macros. Such “conditional-macro” and/or “parameterized-macro” control could also be implemented in software, firmware, and/or hard-wired logic.

Any of the above implementations can be used individually or in combination. Additional extensions and variations along these lines are anticipated and provided for by the invention.

### CLOSING REMARKS

The terms “certain embodiments”, “an embodiment”, “embodiment”, “embodiments”, “the embodiment”, “the embodiments”, “one or more embodiments”, “some embodiments”, and “one embodiment” mean one or more (but not all) embodiments unless expressly specified otherwise. The terms “including”, “comprising”, “having” and variations thereof mean “including but not limited to”, unless expressly specified otherwise. The enumerated listing of items does not imply that any or all of the items are mutually exclusive, unless expressly specified otherwise. The terms “a”, “an” and “the” mean “one or more”, unless expressly specified otherwise.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

While the invention has been described in detail with reference to used embodiments, various modifications within the scope of the invention will be apparent to those of ordinary skill in this technological field. It is to be appreciated that features described with respect to one embodiment typically can be applied to other embodiments.

The invention can be embodied in other specific forms without departing from the spirit or essential characteristics thereof. The present embodiments are therefore to be, considered in all respects as illustrative and not restrictive, the scope of the invention being indicated by the appended claims rather than by the foregoing description and all changes which come within the meaning and range of equivalency of the claims are therefore intended to be embraced therein.

Although exemplary embodiments have been provided in detail, various changes, substitutions and alternations could be made thereto without departing from spirit and scope of the disclosed subject matter as defined by the appended claims. Variations described for the embodiments may be realized in any combination desirable for each particular application. Thus particular limitations and embodiment enhancements described herein, which may have particular advantages to a particular application, need not be used for all applications. Also, not all limitations need be implemented in methods, systems, and apparatuses including one or more concepts described with relation to the provided embodiments. Therefore, the invention is properly to be construed with reference to the claims. Furthermore, it is noted that, Applicant's intent is to encompass equivalents of all claim elements, even if amended later during prosecution.

What is claimed is:

1. A valve configuration for a software-controlled system, the valve configuration comprising:
a plurality of ports for connection with at least one external system; and
a plurality of software-controlled valves, mutually connected in a triangular topology, each valve in communication with at least one associated port of the three ports,
wherein the valves are configured to control flows in a manner that in a first interval of time directs flow from a first port of the plurality of ports to a second of the plurality of ports through at least one of the valves, and
wherein the valves are additionally configured to later control flows in a manner that in a second interval of time directs flow from a third port of the plurality of ports to the second of the plurality of ports through the same at least one valve.

2. The valve configuration of claim 1, wherein the valves are additionally configured to later control flows in a manner that in a third interval of time directs flow from a third port of the plurality of ports to the first of the three ports through at least one valve of the plurality of valves.

3. The valve configuration of claim 1, wherein at least one of the valves is a single-pole double-throw (SPDT) valve.

4. The valve configuration of claim 1, wherein at least one of the valves is a single-pole single-throw (SPST) valve or on/off valve.

5. The valve configuration of claim 1, further configured so that at one interval of time fluid flows through the first and second valve and at a later interval of time the third port receives a pressurized gas.

6. The valve configuration of claim 1, further configured so that at one interval of time fluid flows through the first and second valve and at a later interval of time the third port receives a liquid cleaning solvent.

7. The valve configuration of claim 1, further configured to facilitate the return unused materials abandoned in conduits and valve passages along a transmission path back to the fluid source.

8. The valve configuration of claim 1, further configured to facilitate the return unused materials abandoned in conduits and valve passages along a transmission path to another location.

9. The valve configuration of claim 1, further configured to facilitate the creation of a small-volume burst of fluid.

10. The valve configuration of claim 1, wherein each valve can be controlled individually.

11. The valve configuration of claim 1, wherein pairs of valves can be controlled simultaneously.

12. The valve configuration of claim 1, further configured to be controlled by “macro” control operations so as to operate groups of valves at the same time.

13. The valve configuration of claim 12, further configured for receiving at least one conditional input and using the value of that input to affect the behavior of the group operation by the “macro” control operation.

14. The valve configuration of claim 12, further configured to be receiving at least one parameter and using the value of that parameter to affect the behavior of the group operation by the “macro” control operation.

15. The valve configuration of claim 12, wherein the “macro” control is implemented at least in part via hardware.

16. The valve configuration of claim 12, wherein the “macro” control is implemented at least in part via firmware.

17. The valve configuration of claim 1, further configured to be controlled by “macro” control operations so as to operate groups of valves in a time-defined sequence.

18. The valve configuration of claim 17, further configured for receiving at least one conditional input and using the value of that input to affect the behavior of the group operation by the “macro” control operation.

19. The valve configuration of claim 17, further configured to be receiving at least one parameter and using the value of that parameter to affect the behavior of the group operation by the “macro” control operation.

20. The valve configuration of claim 17, wherein the “macro” control is implemented at least in part via hardware.

21. The valve configuration of claim 17, wherein the “macro” control is implemented at least in part via firmware.
